(19) United States
(12) Patent Application Publication
(10) Pub. No.: US 2026/0026211 A1
(43) Pub. Date: Jan. 22, 2026

(54) DISPLAY DEVICE, METHOD FOR MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: HYUNWOO NOH, Yongin-si (KR); YOUNGMIN KIM, Yongin-si (KR); HAEIL PARK, Yongin-si (KR); MOONJUNG BAEK, Yongin-si (KR); DAEHO LEE, Yongin-si (KR); SUJI HAN, Yongin-si (KR)

(21) Appl. No.: 19/231,907

(22) Filed: Jun. 9, 2025

(30) Foreign Application Priority Data
Jul. 17, 2024 (KR) 10-2024-0094697
Dec. 11, 2024 (KR) 10-2024-0183456

(51) Int. Cl. H10K 59/124; H10K 59/12; H10K 59/121; H10K 59/122; H10K 59/123; H10K 59/38; H10K 59/80; H10K 71/60

(52) U.S. Cl. CPC H10K 59/124; H10K 59/1201; H10K 59/122; H10K 59/123; H10K 59/38; H10K 59/80517; H10K 59/80518; H10K 71/60; H10K 59/1213

(57) ABSTRACT

A display device includes a base layer including first to third light-emitting regions and a non-light-emitting region, a circuit element layer on the base layer and including an inorganic insulating layer covering a plurality of transistors and an organic insulating layer on the inorganic insulating layer, plugs in through-holes defined in the organic insulating layer, the plugs electrically connected to the transistors, lower electrodes electrically connected to the plugs and including first to third reflective electrodes respectively overlapping the first to third light-emitting regions and first to third transparent electrodes respectively on and electrically connected to the first to third reflective electrodes, an organic layer on the lower electrodes and including a light-emitting layer, and an upper electrode on the organic layer, wherein the plugs may protrude toward the lower electrodes beyond an upper surface of the organic layer.

### CROSS-REFERENCE TO RELATED APPLICATIONS

The present application claims priority to and the benefits of Korean Patent Application No. 10-2024-0094697, filed on Jul. 17, 2024, in the Korean Intellectual Property Office, and Korean Patent Application No. 10-2024-0183456, filed on Dec. 11, 2024, in the Korean Intellectual Property Office, the entire disclosures of both of which are incorporated herein by reference.

### BACKGROUND

Embodiments of the present disclosure relate to a display device, a method for manufacturing the display device, and an electronic device including the display device.

Electronic devices such as smartphones, digital cameras, notebook computers, navigation systems, and smart televisions, that generally provide images to users, include a display device for displaying such images. The display device generates images and provides the generated images to users through a display screen.

The display device may include a display panel including a plurality of pixels for generating images, a scan driver for applying scan signals to the pixels, and a data driver for applying data voltages to the pixels. The pixels may receive data voltages in response to the scan signals and generate images using the data voltages.

The display panel may include a display region and a non-display region around (e.g., surrounding) the display region, and the pixels can be arranged in the display region. The resolution of the display device improves as the number of pixels arranged in the display region increases. Recently, high-resolution display devices, which have a high number of pixels in the display region, have grown in demand.

The above information disclosed in this Background section is intended to enhance understanding of the background of the disclosure and may contain information that does not constitute prior art.

### SUMMARY

Aspects of one or more embodiments of the present disclosure are directed toward a display device including a display panel that implements high resolution while securing an aperture ratio, a method for manufacturing the display device, and an electronic device including the display device.

Additional aspects will be set forth in part in the description which follows and, in part, will be apparent from the description, or may be learned by practice of the presented embodiments of the disclosure.

One or more embodiments of the present disclosure provide a display device including a base layer which includes first to third light-emitting regions and a non-light-emitting region, a circuit element layer arranged on the base layer and including an inorganic insulating layer covering a plurality of transistors and an organic insulating layer arranged on the inorganic insulating layer, a plurality of plugs arranged in through-holes defined in the organic insulating layer, the plugs electrically connected to the transistors, lower electrodes electrically connected to the plugs and including first to third reflective electrodes respectively overlapping the first to third light-emitting regions and first to third transparent electrodes respectively arranged on and electrically connected to the first to third reflective electrodes, an organic layer arranged on the lower electrode and including a light-emitting layer, and an upper electrode arranged on the organic layer, wherein the plugs protrude toward the lower electrodes beyond an upper surface of the organic insulating layer.

In one or more embodiments of the present disclosure, a method for manufacturing a display device includes: preparing (or supplying) a base layer including first to third light-emitting regions and a non-light-emitting region, forming an inorganic insulating layer on the base layer and covering a plurality of transistors, and forming a plurality of plugs on the inorganic insulating layer and electrically connected to the transistors, applying an organic material onto the inorganic insulating layer and the plugs, hardening (e.g., curing) the organic material, and then etching a portion of the organic material to form an organic insulating layer, applying (forming) a preliminary reflective electrode onto the organic insulating layer and then etching the preliminary reflective electrode to form first to third reflective electrodes respectively overlapping the first to third light-emitting regions, applying an inorganic material onto the first to third reflective electrodes and then etching the inorganic material to form a differential film on the first reflective electrode and the second reflective electrode, etching the differential film to form a first contact hole overlapping the first reflective electrode and a second contact hole overlapping the second reflective electrode, applying a preliminary transparent electrode onto the differential film and then etching the preliminary transparent electrode to form first to third transparent electrodes on the first to third reflective electrodes, respectively, forming an organic layer on the first to third transparent electrodes, and forming an upper electrode on the organic layer, wherein the plugs protrude upward from an upper surface of the organic insulating layer.

In one or more embodiments of the present disclosure, an electronic device includes a case including a first case and a second case arranged on one side of the first case, a display device arranged between the first case and the second case, and an optical system arranged inside the first case, wherein the display device includes a base layer including first to third light-emitting regions and a non-light-emitting region, a circuit element layer arranged on the base layer and including an inorganic insulating layer covering a plurality of transistors and an organic insulating layer arranged on the inorganic insulating layer, a plurality of plugs arranged in through-holes defined in the organic insulating layer, the plugs electrically connected to the transistors, lower electrodes electrically connected to the plugs and including first to third reflective electrodes respectively overlapping the first to third light-emitting regions and first to third transparent electrodes forming arranged on and electrically connected to the first to third reflective electrodes, an organic layer arranged on the lower electrode and including a light-emitting layer, and an upper electrode arranged on the organic layer, wherein the plugs protrude toward the lower electrodes beyond an upper surface of the organic insulating layer.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a block diagram of an electronic device according to one or more embodiments of the present disclosure;

FIG. 2 illustrates schematic diagrams of electronic devices according to one or more embodiments of the present disclosure;

FIG. 3 is a perspective view showing a head-mounted display, according to one or more embodiments of the present disclosure;

FIG. 4 is an exploded perspective view of the head-mounted display of FIG. 3, according to one or more embodiments of the present disclosure;

FIG. 5 is a perspective view of a display device of FIG. 4, according to one or more embodiments of the present disclosure;

FIG. 6 is a cross-sectional view of the display device of FIG. 5, according to one or more embodiments of the present disclosure;

FIG. 7 is a cross-sectional view of a display panel of FIG. 6, according to one or more embodiments of the present disclosure;

FIG. 8 is a plan view of the display panel of FIG. 7, according to one or more embodiments of the present disclosure;

FIG. 9 is an enlarged plan view illustrating a portion of a display region of the display panel, according to one or more embodiments of the present disclosure;

FIG. 10 is a cross-sectional view of a first light-emitting region of FIG. 9, according to one or more embodiments of the present disclosure;

FIG. 11 is a cross-sectional view of the portion of the display region of the display panel taken along the line I-I′ of FIG. 9, according to one or more embodiments of the present disclosure;

FIG. 12 is a cross-sectional view of a light-emitting element according to one or more embodiments of the present disclosure;

FIG. 13 is a cross-sectional view of the portion of the display region taken along the line I-I′ of FIG. 9, according to one or more embodiments of the present disclosure; and

FIGS. 14A to 14M are cross-sectional views for explaining the manufacturing of lower electrodes illustrated in FIG. 11, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In addition, in the drawings, the thicknesses, ratios, and dimensions of elements may be exaggerated for clarity and/or for effective description of the technical contents.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

A display device according to one or more embodiments of the present disclosure may be applied to one or more suitable electronic devices. An electronic device according to one or more embodiments of the present disclosure may include the display device described in more detail below and may further include a module or device having additional functions in addition to the display device.

Hereinafter, embodiments of the present disclosure will be described in more detail with reference to the drawings.

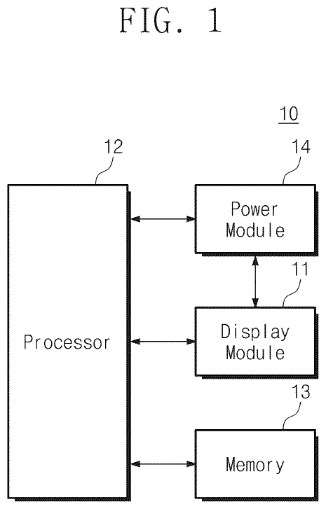

FIG. 1 is a block diagram of an electronic device according to one or more embodiments of the present disclosure.

Referring to FIG. 1, the electronic device 10 according to one or more embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts power supplied by the power supply module and generates power necessary for the operation of the electronic device 10.

At least one of the components of the electronic device 10 described above may be included in the display device according to one or more embodiments of the present disclosure. In addition, some of the individual modules functionally included in one module may be included in the display device, and others may be provided separately from the display device. For example, the display module 11 may be included in the display device, and the processor 12, the memory 13, and the power module 14 may be provided in the form of other devices within the electronic device 10 other than the display device.

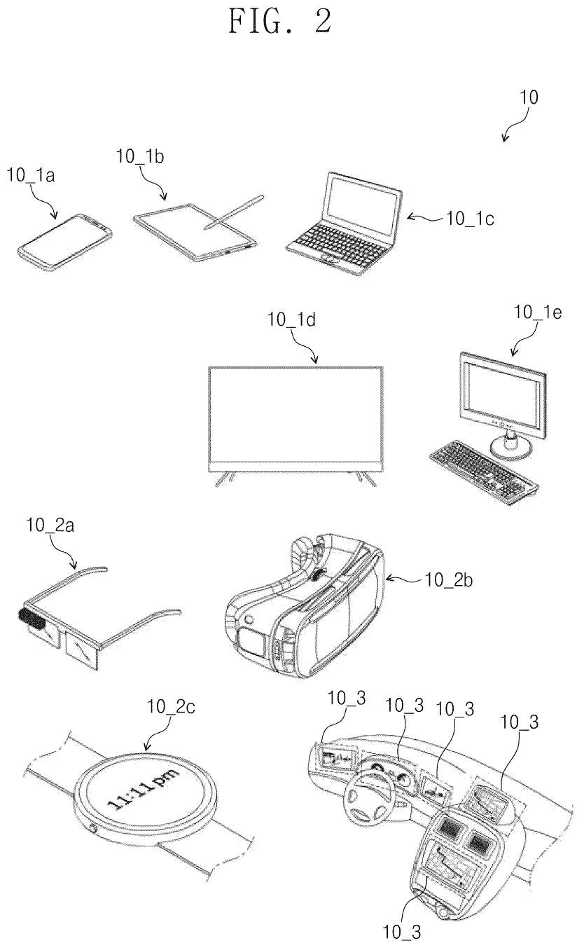

FIG. 2 illustrates schematic diagrams of electronic devices according to one or more embodiments of the present disclosure.

Referring to FIG. 2, one or more suitable electronic devices 10 to which a display device according to one or more embodiments of the present disclosure is applied may include not only electronic devices for displaying images, such as a smart phone 10_1a, a tablet PC 10_1b, a laptop 10_1c, a television 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a vehicle instrument panel, a center fascia, a center information display (CID) positioned on a dashboard, and a room mirror display.

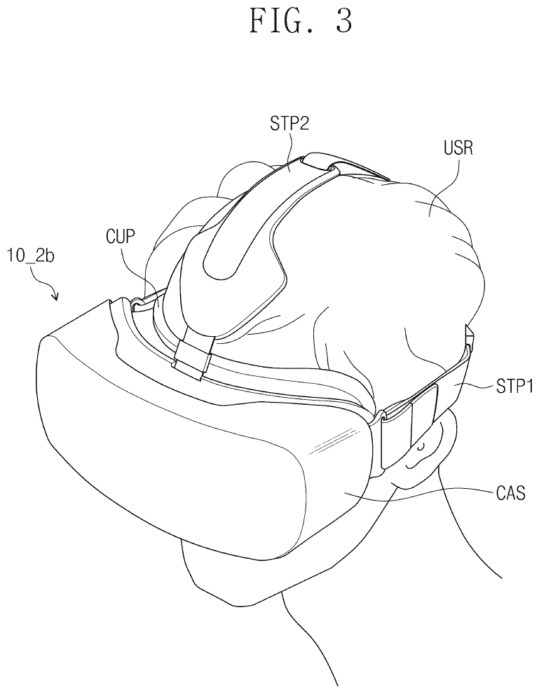

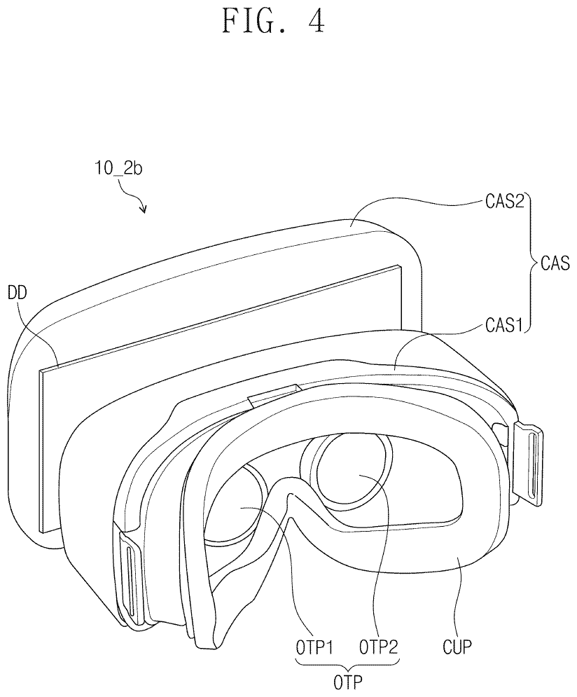

FIG. 3 is a perspective view showing a head-mounted display, such as the one illustrated in FIG. 2, according to one or more embodiments of the present disclosure. FIG. 4 is an exploded perspective view of the head-mounted display of FIG. 3, according to one or more embodiments of the present disclosure.

As an example, the head-mounted display 10_2b among the electronic devices 10 illustrated in FIG. 2 will be mainly described.

Hereinafter, the head-mounted display 10_2b may be referred to as an electronic device 10_2b.

Referring to FIGS. 3 and 4, the electronic device 10_2b according to one or more embodiments of the present disclosure may be worn on the head of a user USR.

The electronic device 10_2b may block or reduce the peripheral vision of the user USR and provide an image to the user USR. The electronic device 10_2b may provide virtual reality to the user USR.

The electronic device 10_2b may include a case portion CAS, a cushion portion CUP, a display device DD, and strap portions STP1 and STP2. The case portion CAS may be worn by the user USR. The display device DD for displaying an image, an acceleration sensor, and/or the like may be accommodated inside the case portion CAS. The display device DD will be described in more detail below.

The acceleration sensor may sense the movement of the user USR and transmit a set or predetermined signal to the display device DD. Accordingly, the display device DD may provide an image corresponding to a change in the gaze of the user USR. As a result, the user USR may experience virtual reality similar to actual reality.

The cushion portion CUP may be arranged between the case portion CAS and the user USR. The cushion portion CUP may include a material that is freely deformable. For example, the cushion portion CUP may include a polymer resin (for example, polyurethane, polycarbonate, polypropylene, and/or polyethylene). In one or more embodiments, the cushion portion CUP may include a sponge formed by foaming and molding a rubber solution, a urethane-based material, or an acrylic-based material.

The cushion portion CUP may allow the case portion CAS to closely fit the user USR, thereby improving the wearing comfort of the user USR. The cushion portion CUP may be detachable from the case portion CAS.

The strap portions STP1 and STP2 may be coupled to the case portion CAS to allow the case portion CAS to be easily worn by the user USR. The strap portions STP1 and STP2 may include a first strap portion STP1 and a second strap portion STP2.

The first strap portion STP1 may be worn around the head of the user USR. The first strap portion STP1 may fix the case portion CAS to the user USR so that the case portion CAS may closely fit the head of the user USR.

The second strap portion STP2 may connect the case portion CAS and the first strap portion STP1 to each other along the upper part of the head of the user USR. The second strap portion STP2 may prevent or reduce the likelihood of the case portion CAS slipping down.

Referring to FIG. 4, the case portion CAS may include a first case portion CAS1 and a second case portion CAS2. The first case portion CAS1 and the second case portion CAS2 may be separated from each other.

The display device DD may be arranged between the first case portion CAS1 and the second case portion CAS2. The first case portion CAS1 and the second case portion CAS2 may be coupled to each other to accommodate the display device DD inside the case portion CAS. For example, the display device DD may provide left-eye and right-eye images to a user. Accordingly, the display device DD may provide stereoscopic images to the user.

An optical system OTP may be arranged inside the first case portion CAS1. The optical system OTP may magnify an image provided from the display device DD. The optical system OTP may be arranged between the display device DD and the eyes of the user USR. The optical system OTP may include a left-eye optical system OTP1 and a right-eye optical system OTP2. The left-eye optical system OTP1 may magnify an image and provide it to the left pupil of the user USR, and the right-eye optical system OTP2 may magnify an image and provide it to the right pupil of the user USR.

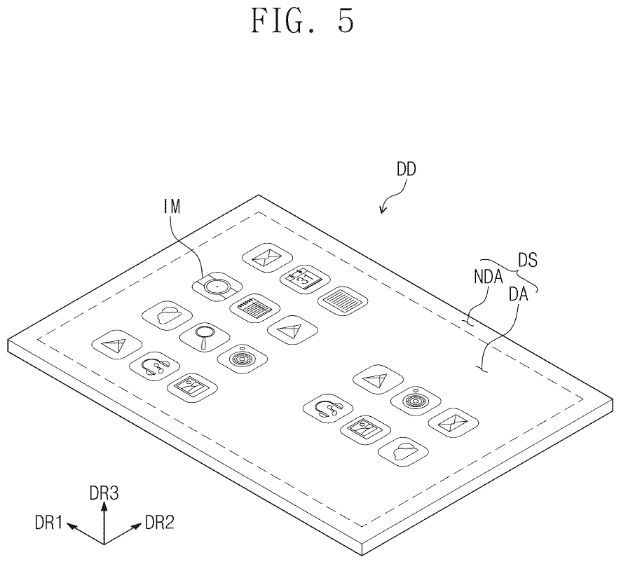

FIG. 5 is a perspective view of the display device of FIG. 4, according to one or more embodiments of the present disclosure.

Referring to FIG. 5, the display device DD according to one or more embodiments of the present disclosure may have a rectangular shape with long sides extending in a first direction DR1 and short sides extending in a second direction DR2 crossing the first direction DR1. Without being limited thereto, however, the display device DD may have one or more suitable shapes such as a circle or a polygon.

Hereinafter, a direction substantially normal (e.g., perpendicular) to a plane defined by the first direction DR1 and the second direction DR2 is defined as a third direction DR3. In this specification, the meaning of “when viewed on a plane (e.g., in a plan view)” is defined as a state viewed from the third direction DR3.

The upper surface of the display device DD may be defined as a display surface DS and may have a plane defined by the first direction DR1 and the second direction DR2. Images IM generated in the display device DD may be provided to a user through the display surface DS.

The display surface DS may include a display region DA and a non-display region NDA around (e.g., surrounding) the display region DA. The display region DA may display an image, and the non-display region NDA may not display an image. The non-display region NDA may be around (e.g., surround) the display region DA and define a border of the display device DD printed in a set or predetermined color.

The display device DD may be used in large electronic devices such as televisions, monitors, or external billboards. In one or more embodiments, the display device DD may be used in small and medium-sized electronic devices such as personal computers, notebook computers, personal digital terminals, car navigation systems, game consoles, smart phones, tablets, or cameras. However, these are presented only as example embodiments, and the display device DD may be used in other electronic devices as long as they do not depart from the scope and spirit of the present disclosure.

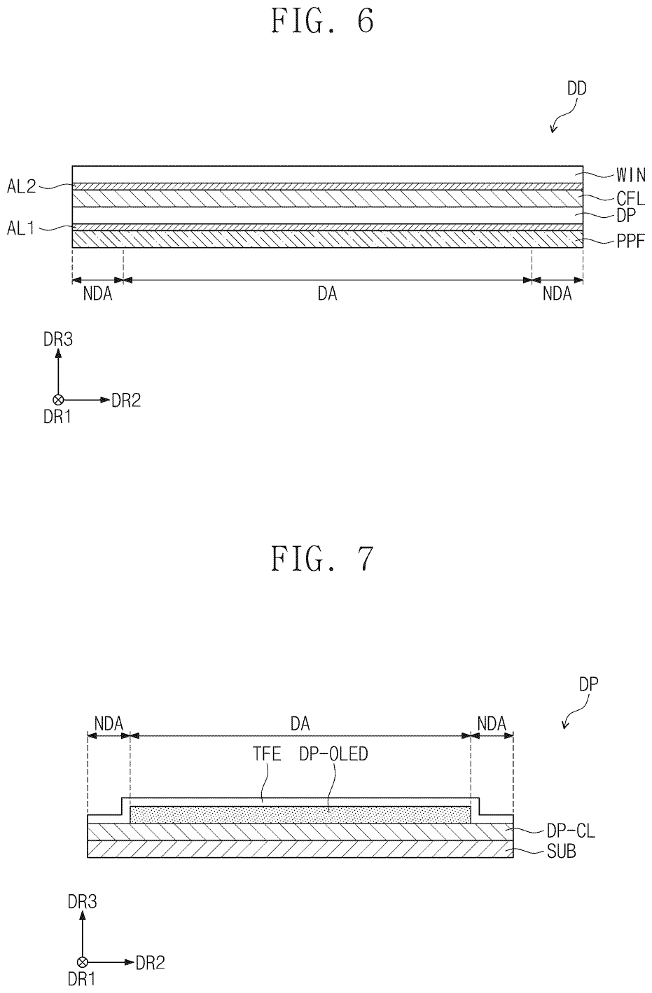

FIG. 6 is a cross-sectional view of the display device of FIG. 5, according to one or more embodiments of the present disclosure.

As an example, FIG. 6 illustrates a cross-section of the display device DD viewed from the first direction DR1.

Referring to FIG. 6, the display device DD may include a display panel DP, a color filter layer CFL, a window WIN, a panel protection film PPF, and first and second adhesive layers AL1 and AL2.

The display panel DP may be a flexible display panel. The display panel DP according to one or more embodiments of the present disclosure may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and/or the like. Hereinafter, the display panel DP is described as an organic light-emitting display panel according to embodiments of the present disclosure.

An input sensing portion may be arranged on the display panel DP. The input sensing portion may include a plurality of sensing portions for sensing an external input in a capacitive manner. The input sensing portion may be manufactured directly on the display panel DP during the manufacturing of the display device DD. Without being limited thereto, however, the input sensing portion may be manufactured as a panel separate from the display panel DP and attached to the display panel DP by an adhesive layer.

A reflection prevention layer may be arranged on the input sensing portion. The reflection prevention layer may be manufactured directly on the input sensing portion during the manufacturing of the display device DD. Without being limited thereto, however, the reflection prevention layer may be manufactured as a separate panel and attached to the input sensing portion by an adhesive layer.

The reflection prevention layer may be defined as an external light reflection prevention film. The reflection prevention layer may reduce the reflectance of external light incident from above the display device DD toward the display panel DP. The external light may not be visually recognized by a user due to the reflection prevention layer.

When external light traveling toward the display panel DP is reflected by the display panel DP like a mirror and provided back to an external user, the user may visually recognize the external light. In order to prevent or reduce such a phenomenon, as an example, the reflection prevention layer may include a plurality of color filters (see, e.g., the color filter layer CFL) that display the same colors as the pixels of the display panel DP.

The color filters may filter the external light into the same colors as the pixels. In such embodiments, the external light may not be visible to the user. Without being limited thereto, however, the reflection prevention layer may include a retarder and/or a polarizer to reduce the reflectance of the external light.

The window WIN may be arranged on the reflection prevention layer (e.g., the color filter layer CFL). The window WIN may protect the display panel DP, the input sensing portion, and the reflection prevention layer from external scratches and impacts.

The panel protection film PPF may be arranged below the display panel DP. The panel protection film PPF may protect the lower portion of the display panel DP. The panel protection film PPF may include a flexible plastic material such as polyethylene terephthalate (PET).

The first adhesive layer AL1 may be arranged between the display panel DP and the panel protection film PPF, and the display panel DP and the panel protection film PPF may be bonded to each other by the first adhesive layer AL1. The second adhesive layer AL2 may be arranged between the window WIN and the reflection prevention layer (e.g., the color filter layer CFL), and the window WIN and the reflection prevention layer/color filter layer CFL may be bonded to each other by the second adhesive layer AL2.

FIG. 7 is a cross-sectional view of the display panel of FIG. 6, according to one or more embodiments of the present disclosure.

For example, FIG. 7 illustrates a cross-section of the display panel DP viewed from the first direction DR1.

Referring to FIG. 7, the display panel DP may include a substrate SUB, a circuit element layer DP-CL arranged on the substrate SUB, a display element layer DP-OLED arranged on the circuit element layer DP-CL, and a thin film encapsulation layer TFE arranged on the display element layer DP-OLED.

The substrate SUB may include a display region DA and a non-display region NDA around (e.g., surrounding) the display region DA. The substrate SUB may include glass or a flexible plastic material such as polyimide (PI). The display element layer DP-OLED may be arranged on (in) the display region DA. The substrate SUB may be referred to as a base layer SUB.

A plurality of pixels may be arranged in the circuit element layer DP-CL and the display element layer DP-OLED. Each of the pixels may include a transistor arranged in the circuit element layer DP-CL and a light-emitting element arranged in the display element layer DP-OLED and connected to the transistor.

The thin film encapsulation layer TFE may be arranged on the display element layer DP-OLED and the circuit element layer DP-CL to cover the display element layer DP-OLED. The thin film encapsulation layer TFE may protect the pixels from moisture, oxygen, and/or external foreign substances.

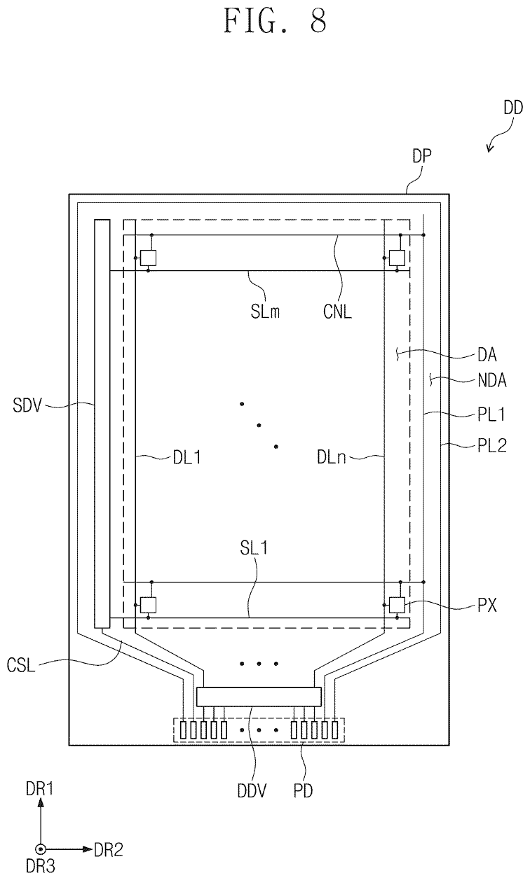

FIG. 8 is a plan view of the display panel of FIG. 7, according to one or more embodiments.

Referring to FIG. 8, the display device DD may include a display panel DP, a scan driver SDV, a data driver DDV, and a plurality of pads PD.

The display panel DP may have a rectangular shape with long sides extending in the first direction DR1 and short sides extending in the second direction DR2, but the shape of the display panel DP is not limited thereto. The display panel DP may include a display region DA and a non-display region NDA around (e.g., surrounding) the display region DA.

The display panel DP may include a plurality of pixels PX, a plurality of scan lines SL1 to SLm, a plurality of data lines DL1 to DLn, a control line CSL, first and second power lines PL1 and PL2, and connection lines CNL, wherein m and n are natural numbers.

The pixels PX may be arranged in the display region DA. The pixels PX may be arranged in a matrix form, but the arrangement form of the pixels PX is not limited thereto.

The scan driver SDV may be arranged in the non-display region NDA adjacent to any one of the long sides of the display panel DP. In one or more embodiments, when viewed on a plane (e.g., in a plan view), the scan driver SDV may be adjacent to the left side of the display panel DP.

The data driver DDV may be arranged in the non-display region NDA adjacent to any one of the short sides of the display panel DP. In one or more embodiments, when viewed on a plane (e.g., in a plan view), the data driver DDV may be adjacent to the lower end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the data driver DDV.

The first power line PL1 may extend in the first direction DR1 to be arranged in the non-display region NDA. The first power line PL1 may be adjacent to a long side of the display panel DP adjacent to which the scan driver SDV is not arranged. For example, the first power line PL1 may be adjacent to the long side of the display panel DP at which the scan driver SDV is not located. The first power line PL1 may be at the opposite side of the display panel DP relative to the scan driver SDV along the second direction DR2.

The connection lines CNL may extend in the second direction DR2 and be arranged in the first direction DR1 to be connected to the first power line PL1 and the pixels PX. A first voltage may be applied to the pixels PX through the first power line PL1 and the connection lines CNL that are connected to each other.

The second power line PL2 may be arranged in the non-display region NDA and extend along the long sides (e.g., both long sides) of the display panel DP and the other short side of the display panel DP along which the data driver DDV is not arranged. The second power line PL2 may be arranged outside the scan driver SDV.

In one or more embodiments, the second power line PL2 may extend toward the display region DA to be connected to the pixels PX. A second voltage may be applied to the pixels PX through the second power line PL2.

The control line CSL may be connected to the scan driver SDV and extend toward the lower end of the display panel DP. A control signal for controlling the operation of the scan driver SDV may be provided to the scan driver SDV through the control line CSL.

The pads PD may be arranged in the non-display region NDA adjacent to the lower end of the display panel DP and may be closer to the lower end of the display panel DP than the data driver DDV. The data driver DDV, the first and second power lines PL1 and PL2, and the control line CSL may be connected to the pads PD. The data lines DL1 to DLn may be connected to the data driver DDV, and the data driver DDV may be connected to the pads PD corresponding to the data lines DL1 to DLn.

In one or more embodiments, the display device DD may further include a timing controller for controlling the operation of the scan driver SDV and the data driver DDV, and a voltage generator for generating the first and second voltages. The timing controller and the voltage generator may be mounted on a printed circuit board and connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn.

The pixels PX may receive the data voltages in response to the scan signals. The pixels PX may display an image by emitting light having a luminance corresponding to the data voltages.

In one or more embodiments of the present disclosure, the size of the pixels PX of the display panel DP may be reduced, and the structure of these pixels PX will be described in more detail below.

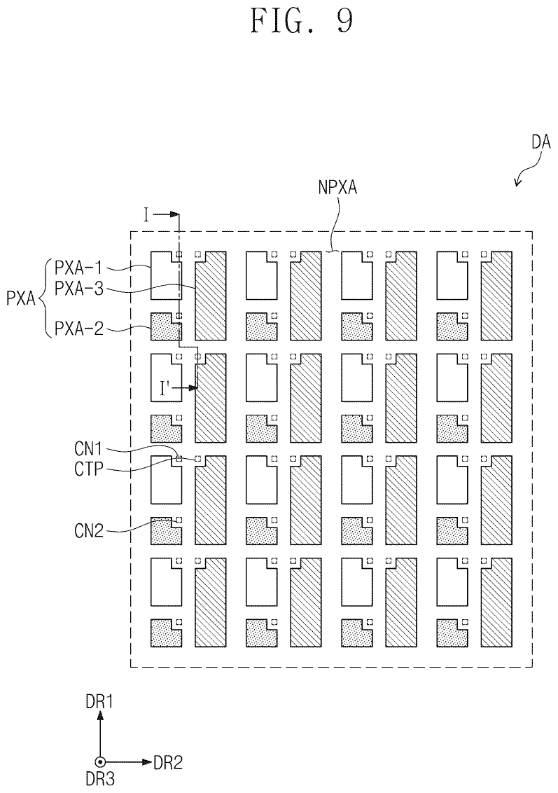

FIG. 9 is an enlarged plan view illustrating a portion of the display region of the display panel according to one or more embodiments of the present disclosure.

Among the components illustrated in FIG. 9, the descriptions of components similar or identical to those described with reference to the aforementioned drawings may not be provided or may be briefly provided.

Referring to FIG. 9, the display region DA may include a light-emitting region PXA and a non-light-emitting region NPXA around (e.g., surrounding) the light-emitting region PXA. The light-emitting region PXA may be provided as a plurality of light-emitting regions PXA. The light-emitting region PXA may include a first light-emitting region PXA-1, a second light-emitting region PXA-2, and a third light-emitting region PXA-3. Hereinafter, for the convenience of explanation, the following description may refer to the first light-emitting region PXA-1, the second light-emitting region PXA-2, and the third light-emitting region PXA-3 in the singular. However, the description may be equally applicable to any of the first, second or third light-emitting regions PX1, PX2, and PX3, respectively, throughout the display region DA.

The first light-emitting region PXA-1, the second light-emitting region PXA-2, and the third light-emitting region PXA-3 may respectively emit light of different wavelength ranges. The first light-emitting region PXA-1 may be to emit a first light, and the second light-emitting region PXA-2 may be to emit a second light different from the first light. The third light-emitting region PXA-3 may be to emit a third light different from the first light and the second light. In one or more embodiments, the first light may be red light, the second light may be green light, and the third light may be blue light.

According to one or more embodiments, the first to third light-emitting regions PXA-1, PXA-2, and PXA-3 may have a (substantially) tetragonal shape. For example, the third light-emitting region PXA-3 may have a (substantially) rectangular shape extending along the first direction DR1. When viewed in the second direction DR2, the first light-emitting region PXA-1 and the second light-emitting region PXA-2 may overlap the third light-emitting region PXA-3. The first to third light-emitting regions PXA-1, PXA-2, and PXA-3 adjacent to each other may define one sub-pixel.

Among the first to third light-emitting regions PXA-1, PXA-2, and PXA-3, the third light-emitting region PXA-3 may have the largest area, and the second light-emitting region PXA-2 may have the smallest area. However, this is an example, and the areas of the first to third light-emitting regions PXA-1, PXA-2, and PXA-3 are not limited thereto.

According to one or more embodiments, a first contact hole CN1 and a second contact hole CN2 may be defined adjacent to the first and second light-emitting regions PXA-1 and PXA-2 among the first to third light-emitting regions PXA-1, PXA-2, and PXA-3. The first contact hole CN1 and the second contact hole CN2 may not be adjacent to the third light-emitting region PXA-3. A connection portion CTP may be defined adjacent to the third light-emitting region PXA-3 among the first to third light-emitting regions PXA-1, PXA-2, and PXA-3. The first contact hole CN1, the second contact hole CN2, and the connection portion CTP may not overlap the first to third light-emitting regions PXA-1, PXA-2, and PXA-3.

Among the two sides of the first light-emitting region PXA-1 which are opposite to each other in the first direction DR1, the first contact hole CN1 may be adjacent to one side of the first light-emitting region PXA-1 which is spaced and/or apart (e.g., spaced apart or separated) from the second light-emitting region PXA-2. For example, the first contact hole CN1 may be at the side of the first light-emitting region PXA-1 along the first direction DR1 that is farthest from the second light-emitting region PXA-2 of the same sub-pixel. Among the two sides of the first light-emitting region PXA-1 which are opposite to each other in the second direction DR2, the first contact hole CN1 may be adjacent to one side of the first light-emitting region PXA-1 which is adjacent to the third light-emitting region PXA-3. For example, the first contact hole CN1 may be at the side of the first light-emitting region PXA-1 along the second direction DR2 that is closest to the third light-emitting region PXA-3 of the same sub-pixel. However, this is an example, and the position of the first contact hole CN1 is not limited thereto.

A corner of the corners of the first light-emitting region PXA-1, which is adjacent to the first contact hole CN1, may have a shape corresponding to the shape of the first contact hole CN1. For example, the first contact hole CN1 may have a tetragonal (or rectangular) shape. The corner of the corners of the first light-emitting region PXA-1, which is adjacent to the first contact hole CN1, may have a shape corresponding to a portion of a tetragon. For example, the corner of the first light-emitting region PXA-1 at which the first contact hole CN1 is located may have an indent, e.g., a rectangular indent in a plan view, that corresponds to the shape of the first contact hole CN1. Thus, in a plan view, the overall shape of the first light-emitting region PXA-1 may be rectangular in shape with a rectangular indentation at the corner of the first light-emitting region PXA-1 at which the first contact hole CN1 is located. In one or more embodiments, the indent of the first light-emitting region PXA-1 may be larger than the first contact hole CN1 such that the first contact hole CN1 is spaced and/or apart (e.g., spaced apart or separated) from the first light-emitting region PXA-1 in a plan view.

Among the two sides of the second light-emitting region PXA-2 which are opposite to each other in the first direction DR1, the second contact hole CN2 may be adjacent to one side of the second light-emitting region PXA-2 which is adjacent to the first light-emitting region PXA-1. For example, the second contact hole CN2 may be at the side of the second light-emitting region PXA-2 along the first direction DR1 that is closest to the first light-emitting region PXA-1 of the same sub-pixel. Among the two sides of the second light-emitting region PXA-2 which are opposite to each other in the second direction DR2, the second contact hole CN2 may be adjacent to one side of the second light-emitting region PXA-2 which is adjacent to the third light-emitting region PXA-3. For example, the second contact hole CN2 may be at the side of the second light-emitting region PXA-2 along the second direction DR2 that is closest to the third light-emitting region PXA-3 of the same sub-pixel. However, this is an example, and the position of the second contact hole CN2 is not limited thereto.

A corner of the corners of the second light-emitting region PXA-2, which is adjacent to the second contact hole CN2, may have a shape corresponding to the shape of the second contact hole CN2. For example, the second contact hole CN2 may have a tetragonal (or rectangular) shape. The corner of the corners of the second light-emitting region PXA-2, which is adjacent to the second contact hole CN2, may have a shape corresponding to a portion of a tetragon. For example, the corner of the second light-emitting region PXA-2 at which the second contact hole CN2 is located may have an indent, e.g., a rectangular indent in a plan view, that corresponds to the shape of the second contact hole CN2. Thus, in a plan view, the overall shape of the second light-emitting region PXA-2 may be rectangular in shape with a rectangular indentation at the corner of the second light-emitting region PXA-2 at which the second contact hole CN2 is located. In one or more embodiments, the indent of the second light-emitting region PXA-2 may be larger than the second contact hole CN2 such that the second contact hole CN2 is spaced and/or apart (e.g., spaced apart or separated) from the second light-emitting region PXA-2 in a plan view.

The connection portion CTP may be defined adjacent to the third light-emitting region PXA-3. Among the two sides of the third light-emitting region PXA-3 which are opposite to each other in the first direction DR1, the connection portion CTP may be arranged on a side of the third light-emitting region PXA-3 which is adjacent to the first light-emitting region PXA-1. For example, the connection portion CTP may be at the side of the third light-emitting region PXA-3 along the first direction DR1 that is closest to the first light-emitting region PXA-1 of the same sub-pixel. Among the two sides of the third light-emitting region PXA-3 which are opposite to each other in the second direction DR2, the connection portion CTP may be arranged on a side of the third light-emitting region PXA-3 which is adjacent to the first light-emitting region PXA-1. For example, the connection portion CTP may be at the side of the third light-emitting region PXA-3 along the second direction DR2 that is closest to the first light-emitting region PXA-1 of the same sub-pixel. However, this is an example, and the position of the connection portion CTP is not limited thereto.

A corner of the corners of the third light-emitting region PXA-3, which is adjacent to the connection portion CTP, may have a shape corresponding to the shape of the connection portion CTP. For example, the connection portion CTP may have a tetragonal (or rectangular) shape. The corner of the corners of the third light-emitting region PXA-3, which is adjacent to the connection portion CTP, may have a shape corresponding to a portion of a tetragon. For example, the corner of the third light-emitting region PXA-3 at which the connection portion CTP is located may have an indent, e.g., a rectangular indent in a plan view, that corresponds to the shape of the connection portion CTP. Thus, in a plan view, the overall shape of the third light-emitting region PXA-3 may be rectangular in shape with a rectangular indentation at the corner of the third light-emitting region PXA-3 at which the connection portion CTP is located. In one or more embodiments, the indent of the third light-emitting region PXA-3 may be larger than the connection portion CTP such that the connection portion CTP is spaced and/or apart (e.g., spaced apart or separated) from the third light-emitting region PXA-3 in a plan view. The first and second contact holes CN1 and CN2 and the connection portion CTP will be described in more detail below.

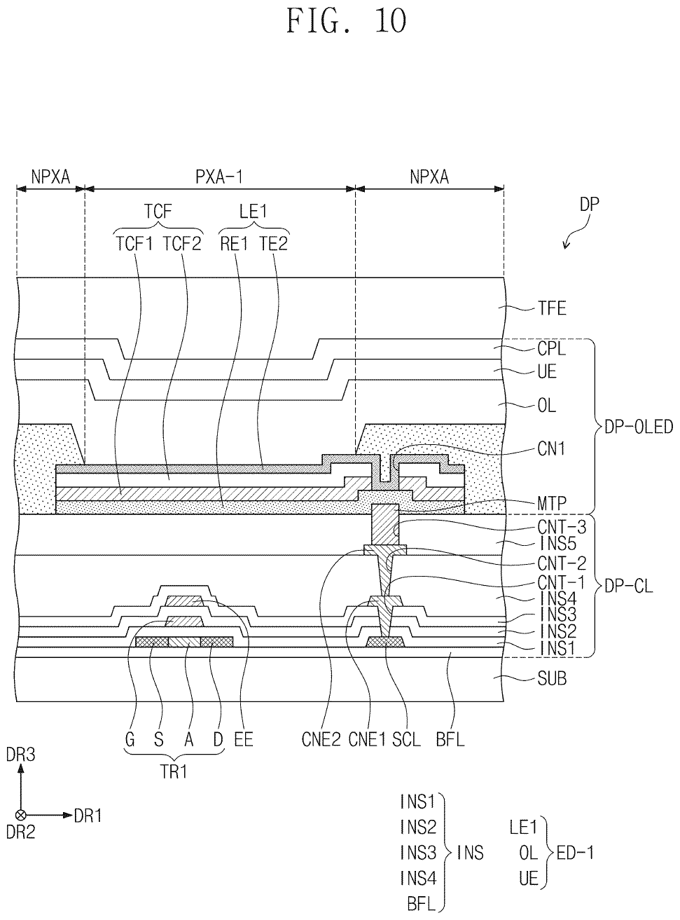

FIG. 10 is a cross-sectional view of the first light-emitting region of FIG. 9, according to one or more embodiments of the present disclosure.

Referring to FIG. 10, the display panel DP may include a base layer SUB, a circuit element layer DP-CL, a display element layer DP-OLED, and a thin film encapsulation layer TFE.

The display panel DP may include a plurality of insulating layers, semiconductor pattern(s), conductive pattern(s), signal line(s), and/or the like. An insulating layer, a semiconductor layer, and a conductive layer may be formed by a method such as coating and deposition. Hereafter, the insulating layer, the semiconductor layer, and the conductive layer may be selectively patterned through photolithography and/or etching processes. In this way, the semiconductor pattern(s), conductive pattern(s), signal line(s), and/or the like included in the circuit element layer DP-CL and the display element layer DP-OLED may be formed.

The base layer SUB may be a silicon substrate. The base layer SUB may be a monocrystalline silicon wafer, a polycrystalline silicon wafer, or an amorphous silicon wafer. The circuit element layer DP-CL may include the insulating layers, semiconductor pattern(s), conductive pattern(s), signal line(s), and/or the like, formed on a silicon wafer.

The circuit element layer DP-CL may be arranged on the base layer SUB. The circuit element layer DP-CL may include a buffer layer BFL, a transistor TR1, a signal transmission region SCL, first to fifth insulating layers INS1, INS2, INS3, INS4, and INS5, an upper electrode EE, a plug MTP, and a plurality of connection electrodes CNE1 and CNE2.

The buffer layer BFL may be arranged on the base layer SUB. The buffer layer BFL may improve the bonding strength between the base layer SUB and the semiconductor pattern (e.g., where the semiconductor pattern includes the semiconductor pattern of the transistor TR1). The buffer layer BFL may include a silicon oxide layer and a silicon nitride layer. The silicon oxide layer and the silicon nitride layer may be alternately stacked.

The semiconductor pattern may be arranged on the buffer layer BFL. The semiconductor pattern may include polysilicon. Without being limited thereto, however, the semiconductor pattern may include amorphous silicon or a metal oxide.

FIG. 10 illustrates a semiconductor pattern corresponding to the first light-emitting region PXA-1, however, semiconductor patterns may be further arranged in a plurality of second and third light-emitting regions PXA-2 and PXA-3 (see, e.g., FIG. 9). The semiconductor patterns may be arranged, for example, according to a specific rule across the plurality of light-emitting regions PXA-1, PXA-2, and PXA-3 (see, e.g., FIG. 9). The semiconductor patterns may have different electrical properties depending on whether or not they are doped. The semiconductor pattern may include a first region having a high doping concentration and a second region having a low doping concentration. The first region may be doped with an N-type (kind) dopant or a P-type (kind) dopant. A P-type (kind) transistor may include the first region doped with a P-type (kind) dopant.

The first region may have a higher conductivity than the second region and substantially serves as an electrode or a signal line. The second region may substantially correspond to an active (or channel) of a transistor. For example, a portion of the semiconductor pattern may be an active of a transistor, another portion thereof may be a source or drain of a transistor, and still another portion thereof may be a conductive region.

A source S, an active A, and a drain D of the transistor TR1 may be formed by and/or as a part of the semiconductor pattern. FIG. 10 illustrates a portion of the signal transmission region SCL formed by and/or as a part of the semiconductor pattern. The signal transmission region SCL may be connected to the drain D of the transistor TR1 on a plane (e.g., in a plan view).

As an example, FIG. 10 illustrates one transistor TR1. In one or more embodiments, a plurality of transistors and at least one capacitor may be electrically connected to each other for each of the first to third light-emitting regions PXA-1 to PXA-3.

The first to fifth insulating layers INS1 to INS5 may be arranged on the buffer layer BFL. The first to fifth insulating layers INS1 to INS5 may be inorganic insulating layers or organic insulating layers. For example, the first to third insulating layers INS1, INS2, and INS3 may be inorganic insulating layers, and the fourth insulating layer INS4 and the fifth insulating layer INS5 may be organic insulating layers.

The first insulating layer INS1 may be arranged on the buffer layer BFL. The first insulating layer INS1 may cover the source S, the active A, and the drain D of the transistor TR1 and the signal transmission region SCL which are arranged on the buffer layer BFL. The gate G of the transistor TR1 may be arranged on the first insulating layer INS1.

The second insulating layer INS2 may be arranged on the first insulating layer INS1 to cover the gate G. The upper electrode EE may be arranged on the second insulating layer INS2. The third insulating layer INS3 may be arranged on the second insulating layer INS2 to cover the upper electrode EE.

A first connection electrode CNE1 may be arranged on the third insulating layer INS3. The first connection electrode CNE1 may be connected to the signal transmission region SCL through a first connection contact hole CNT-1 passing through the first to third insulating layers INS1, INS2, and INS3. The fourth insulating layer INS4 may be arranged on the third insulating layer INS3 to cover the first connection electrode CNE1. The fourth insulating layer INS4 may be an organic insulating layer.

A second connection electrode CNE2 may be arranged on the fourth insulating layer INS4. The second connection electrode CNE2 may be connected to the first connection electrode CNE1 through a second connection contact hole CNT-2 passing through the fourth insulating layer INS4. Hereinafter, the buffer layer BFL and the first to fourth insulating layers INS1, INS2, INS3, and INS4 may be defined as an insulating layer INS.

The fifth insulating layer INS5 may be arranged on the fourth insulating layer INS4 to cover the second connection electrode CNE2. The fifth insulating layer INS5 may be an organic insulating layer. A through-hole CNT-3 may be defined in the fifth insulating layer INS5. The through-hole CNT-3 may overlap the second connection electrode CNE2.

The plug MTP may be arranged in the through-hole CNT-3. The plug MTP may be arranged on the second connection electrode CNE2 through the through-hole CNT-3. The plug MTP may be electrically connected to the transistor TR1 through the second connection electrode CNE2. The plug MTP may include a conductive material. For example, the plug MTP may include a metal.

The upper portion of the plug MTP may be exposed to the outside from the fifth insulating layer INS5. The upper surface of the plug MTP may protrude from the upper surface of the fifth insulating layer INS5. The upper surface of the plug MTP may be higher than the upper surface of the fifth insulating layer INS5.

The display element layer DP-OLED may be arranged on the circuit element layer DP-CL. The thin film encapsulation layer TFE may be arranged on a capping layer CPL of the display element layer DP-OLED. The display element layer DP-OLED and the thin film encapsulation layer TFE will be described in more detail below.

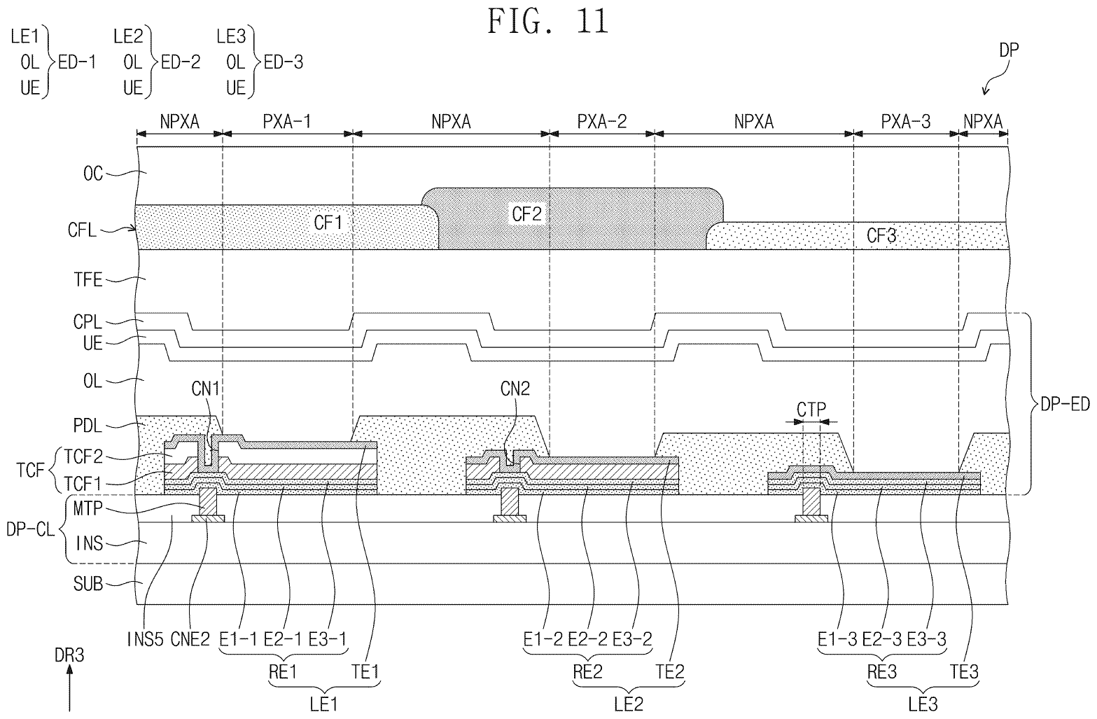

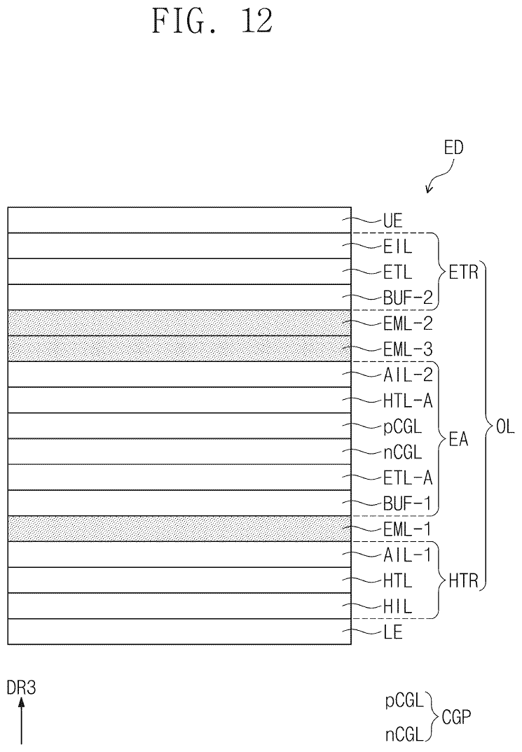

FIG. 11 is a cross-sectional view of a portion of the display region DA of the display panel DP taken along the line I-I′ of FIG. 9, according to one or more embodiments of the present disclosure. FIG. 12 is a cross-sectional view of a light-emitting element according to one or more embodiments of the present disclosure.

For convenience of description, FIG. 11 consolidates several of the layers within the circuit element layer DP-CL.

Among the components illustrated in FIG. 11 to FIG. 12, the descriptions of components similar or identical to those described with reference to the aforementioned drawings may not be provided or may be briefly provided.

Referring to FIGS. 10 and 11, the display element layer DP-OLED may be arranged on the circuit element layer DP-CL. The display element layer DP-OLED may include first to third light-emitting elements ED-1, ED-2, and ED-3, a differential film TCF, a pixel-defining film PDL, and a capping layer CPL.

The first to third light-emitting elements ED-1, ED-2, and ED-3 may be spaced and/or apart (e.g., spaced apart or separated) from each other in one direction (e.g., the first or second direction DR1 or DR2) crossing the third direction DR3 which is the thickness direction. Each of the first to third light-emitting elements ED-1, ED-2, and ED-3 may include a lower electrode LE1, LE2, or LE3, an organic layer OL arranged on the lower electrode LE1, LE2, or LE3, and an upper electrode UE arranged on the organic layer OL.

The lower electrodes LE1, LE2, and LE3 may be arranged on the circuit element layer DP-CL. For example, the lower electrodes LE1, LE2, and LE3 may be arranged on the upper surface of the fifth insulating layer INS5, as illustrated, for example, in FIG. 10.

The lower electrodes LE1, LE2, and LE3 may cover the plugs MTP. The lower electrodes LE1, LE2, and LE3 may be in contact with the plugs MTP. The lower electrodes LE1, LE2, and LE23 may be electrically connected to the transistor TR1 through the plugs MTP.

The lower electrodes LE1, LE2, and LE3 may include reflective electrodes RE1, RE2, and RE3 arranged on the circuit element layer DP-CL and transparent electrodes TE1, TE2, and TE3 arranged on the reflective electrodes RE1, RE2, and RE3. In this specification, the lower electrodes LE1, LE2, and LE3 may refer to “anodes”. The lower electrode LE1, LE2, or LE3 may include a structure in which the reflective electrode RE1, RE2, or RE3 and the transparent electrode TE1, TE2, or TE3 are stacked.

The reflective electrodes RE1, RE2, and RE3 may include a first reflective electrode RE1 included in the first light-emitting element ED-1, a second reflective electrode RE2 included in the second light-emitting element ED-2, and a third reflective electrode RE3 included in the third light-emitting element ED-3.

Each of the reflective electrodes RE1, RE2, and RE3 may cover a corresponding plug MTP among the plugs MTP that are located at each of the first to third light-emitting elements ED-1, ED-2, and ED-3. Portions of the reflective electrodes RE1, RE2, and RE3 overlapping the plugs MTP may protrude from the surroundings (e.g., portions of the reflective electrodes RE1, RE2, and RE3 overlapping the plugs MTP may protrude further than portions of the reflective electrodes RE1, RE2, and RE3 not overlapping the plugs MTP). The upper surfaces of the reflective electrodes RE1, RE2, and RE3 overlapping the plugs MTP may have inclined surfaces relative to the portions of the reflective electrodes RE1, RE2, and RE3 not overlapping the plugs MTP. The reflective electrodes RE1, RE2, and RE3 may be in contact with the plugs MTP and electrically connected to the transistor TR1.

Each of the first reflective electrode RE1, the second reflective electrode RE2, and the third reflective electrode RE3 may include a three-layer structure. Each of the first reflective electrode RE1, the second reflective electrode RE2, and the third reflective electrode RE3 may include a first layer E1-1, E1-2, or E1-3, a second layer E2-1, E2-2, or E2-3, and a third layer E3-1, E3-2, or E3-3, respectively, that are sequentially stacked.

The first layers E1-1, E1-2, and E1-3 may cover the plugs MTP. Portions of the first layers E1-1, E1-2, and E1-3 overlapping the plugs MTP may include inclined upper surfaces (e.g., the portions of the first layers E1-1, E1-2, and E1-3 covering the plugs MTP may be higher than portions of the first layers E1-1, E1-2, and E1-3 not covering the plugs MTP in the third direction DR3, and portions of the first layers E1-1, E1-2, and E1-3 not covering the plugs MTP that are adjacent to the portions of the first layers E1-1, E1-2, and E1-3 covering the plugs MTP may be inclined up to the portions of the first layers E1-1, E1-2, and E1-3 covering the plugs MTP). The lower surfaces of the second layers E2-1, E2-2, and E2-3 may have a shape corresponding to the upper surfaces of the first layers E1-1, E1-2, and E1-3. Portions of the second layers E2-1, E2-2, and E2-3 overlapping the plugs MTP may include inclined upper surfaces (e.g., the portions of the second layers E2-1, E2-2, and E2-3 overlapping the plugs MTP may be higher than portions of the second layers E2-1, E2-2, and E2-3 not overlapping the plugs MTP in the third direction DR3 and portions of the second layers E2-1, E2-2, and E2-3 not overlapping the plugs MTP that are adjacent to the portions of the second layers E2-1, E2-2, and E2-3 overlapping the plugs MTP may be inclined up to the portions of the second layers E2-1, E2-2, and E2-3 overlapping the plugs MTP). The lower surfaces of the third layers E3-1, E3-2, and E3-3 may have shapes corresponding to the upper surfaces of the second layers E2-1, E2-2, and E2-3. Portions of the third layers E3-1, E3-2, and E3-3 overlapping the plugs MTP may include inclined upper surfaces (e.g., the portions of the third layers E3-1, E3-2, and E3-3 overlapping the plugs MTP may be higher than portions of the third layers E3-1, E3-2, and E3-3 not overlapping the plugs MTP in the third direction DR3, and portions of the third layers E3-1, E3-2, and E3-3 not overlapping the plugs MTP that are adjacent to the portions of the third layers E3-1, E3-2, and E3-3 overlapping the plugs MTP may be inclined up to the portions of the third layers E3-1, E3-2, and E3-3 overlapping the plugs MTP).

Each of the first layers E1-1, E1-2, and E1-3 and the third layers E3-1, E3-2, and E3-3 may include a transparent conductive oxide. Each of the first layers E1-1, E1-2, and E1-3 and the third layers E3-1, E3-2, and E3-3 may include at least one selected from the group consisting of an indium tin oxide (ITO), an indium zinc oxide (IZO), an indium gallium zinc oxide (IGZO), a zinc oxide (ZnOₓ) or an indium oxide (In₂O₃), and an aluminum-doped zinc oxide (AZO). For example, each of the first layer E1-1, E1-2, and E1-3 and the third layer E3-1, E3-2, and E3-3 may include an indium tin oxide (ITO) or an indium zinc oxide (IZO).

The second layers E2-1, E2-2, and E2-3 may include a reflective metal material. The second layers E2-1, E2-2, and E2-3 may include a metal having high reflectance, a metal oxide having high reflectance, a metal nitride having high reflectance, and/or the like. The second layers E2-1, E2-2, and E2-3 may include any one or more of Ag, Mg, Cu, Al, Pt, Pd, Au, Ni, Nd, Ir, Cr, Li, Ca, LiF/Ca, LiF/AI, Mo, and/or Ti having high reflectance. For example, the second layers E2-1, E2-2, and E2-3 may include Ag.

The transparent electrodes TE1, TE2, and TE3 may include a first transparent electrode TE1 included in the first light-emitting element ED-1, a second transparent electrode TE2 included in the second light-emitting element ED-2, and a third transparent electrode TE3 included in the third light-emitting element ED-3.

Each of the first transparent electrode TE1, the second transparent electrode TE2, and the third transparent electrode TE3 may include a transparent conductive oxide. Each of the first transparent electrode TE1, the second transparent electrode TE2, and the third transparent electrode TE3 may include at least one selected from the group consisting of an indium tin oxide (ITO), an indium zinc oxide (IZO), an indium gallium zinc oxide (IGZO), a zinc oxide (ZnOₓ) or an indium oxide (In₂O₃), and an aluminum-doped zinc oxide (AZO). For example, each of the first transparent electrode TE1, the second transparent electrode TE2, and the third transparent electrode TE3 may include an indium tin oxide (ITO) or an indium zinc oxide (IZO).

The differential film TCF may be arranged between at least a portion of the reflective electrode RE1, RE2, or RE3 and at least a portion of the transparent electrode TE1, TE2, or TE3. The differential film TCF may be arranged between at least a portion of the reflective electrode RE1, RE2, or RE3 and at least a portion of the transparent electrode TE1, TE2, or TE3 to adjust the resonance distance of each of the first to third light-emitting elements ED-1, ED-2, and ED-3. The differential film TCF may be arranged between at least a portion of the reflective electrode RE1, RE2, or RE3 and at least a portion of the transparent electrode TE1, TE2, or TE3, allowing the reflective electrode RE1, RE2, or RE3 and the transparent electrode TE1, TE2, or TE3 to be spaced and/or apart (e.g., spaced apart or separated) from each other, and this may be designed for light emitted by each of the first to third light-emitting elements ED-1, ED-2, and ED-3 to create an optimal or suitable resonance frequency that induces optical resonance at a specific wavelength.

According to one or more embodiments of the present disclosure, the lower electrodes LE1, LE2, and LE3 may include only the reflective electrodes RE1, RE2, and RE3 and may not include (e.g., may exclude) the transparent electrodes TE1, TE2, and TE3. The lower electrodes LE1, LE2, and LE3 may include the reflective electrodes RE1, RE2, and RE3, and the reflective electrodes RE1, RE2, and RE3 may include, for example, titanium nitride (TiN). At least a portion of the differential film TCF may be arranged on the reflective electrodes RE1, RE2, and RE3.

The differential film TCF may include a first inorganic film TCF1 and a second inorganic film TCF2. The first inorganic film TCF1 may be arranged between the first reflective electrode RE1 and the first transparent electrode TE1. The first inorganic film TCF1 may be arranged between the second reflective electrode RE2 and the second transparent electrode TE2.

The second inorganic film TCF2 may be arranged between the first reflective electrode RE1 and the first transparent electrode TE1. The second inorganic film TCF2 may be arranged only between the first reflective electrode RE1 and the first transparent electrode TE1. The second inorganic film TCF2 may not be arranged between the second reflective electrode RE2 and the second transparent electrode TE2 and may not be arranged between the third reflective electrode RE3 and the third transparent electrode TE3.

The second inorganic film TCF2 may not be arranged between the second reflective electrode RE2 and the second transparent electrode TE2 and between the third reflective electrode RE3 and the third transparent electrode TE3 and may be spaced and/or apart (e.g., spaced apart or separated) from each of the second reflective electrode RE2 and the third reflective electrode RE3.

Without being limited thereto, however, the first inorganic film TCF1 may not be arranged between the second reflective electrode RE2 and the second transparent electrode TE2 and the second inorganic film TFC2 may be arranged between the second reflective electrode RE2 and the second transparent electrode TE2. The present disclosure is not limited to any one embodiment.

Both the first inorganic film TCF1 and the second inorganic film TCF2 may be arranged between the first reflective electrode RE1 and the first transparent electrode TE1 so that the first reflective electrode RE1 and the first transparent electrode TE1 may be spaced and/or apart (e.g., spaced apart or separated) from each other by a first distance in the third direction DR3 that is the thickness direction of the display panel DP. The first inorganic film TCF1 may be arranged between the second reflective electrode RE2 and the second transparent electrode TE2 so that the second reflective electrode RE2 and the second transparent electrode TE2 may be spaced and/or apart (e.g., spaced apart or separated) from each other by a second distance in the third direction DR3 that is the thickness direction of the display panel DP. The first distance may be greater than the second distance.

Although FIGS. 10 and 11 illustrate that the side surfaces of the first inorganic film TCF1 and the second inorganic film TCF2 are aligned with the side surfaces of the first reflective electrode RE1, the present disclosure is not limited thereto, and the side surfaces of the first inorganic film TCF1 and the second inorganic film TCF2 may extend to the non-light-emitting region NPXA. The present disclosure is not limited to any one embodiment.

Each of the first inorganic film TCF1 and the second inorganic film TCF2 includes an inorganic material. Each of the first inorganic film TCF1 and the second inorganic film TCF2 may include at least one of silicon oxide (SiOₓ), silicon nitride (SiNₓ), and/or silicon oxynitride (SiOₓN_{y}). Each of the first inorganic film TCF1 and the second inorganic film TCF2 may include, for example, silicon oxide (SiOₓ).

The thickness of each of the first inorganic film TCF1 and the second inorganic film TCF2 may be, for example, about 100 angstroms to about 3000 angstroms. The thickness of the pixel-defining film PDL may be, for example, about 500 angstroms to about 3000 angstroms.

Contact holes CN1 or CN2 may be defined in the differential film TCF. A first contact hole CN1 may be defined by the first inorganic film TCF1 and the second inorganic film TCF2 that are arranged on the first reflective electrode RE1. A second contact hole CN2 may be defined by the first inorganic film TCF1 arranged on the second reflective electrode RE2. The depth of the first contact hole CN1 may be greater than the depth of the second contact hole CN2. The width of the first contact hole CN1 may be equal to or greater than the width of the second contact hole CN2. The first contact hole CN1 and the second contact hole CN2 may overlap the plugs MTP.

According to one or more embodiments of the present disclosure, the transparent electrodes TE1, TE2, and TE3 may be in contact with the reflective electrodes RE1, RE2, and RE3. The transparent electrodes TE1, TE2, and TE3 may be in contact with the reflective electrodes RE1, RE2, and RE3 so as to provide charges to a hole transport region HTR (see, e.g., FIG. 12) arranged on the transparent electrodes TE1, TE2, and TE3.

According to one or more embodiments the present disclosure, as the first inorganic film TCF1 and the second inorganic film TCF2 are arranged between the first reflective electrode RE1 and the first transparent electrode TE1, the first transparent electrode TE1 may be in contact with the first reflective electrode RE1 through the first contact hole CN1 passing through the first inorganic film TCF1 and the second inorganic film TCF2. The first contact hole CN1 may expose a portion of the first reflective electrode RE1 by passing through the first inorganic film TCF1 and the second inorganic film TCF2. The first transparent electrode TE1 may be arranged in the first contact hole CN1 and come into contact with (e.g., may contact) the first reflective electrode RE1.

According to one or more embodiments, the second contact hole CN2 may be defined adjacent to the second light-emitting region PXA-2. The second contact hole CN2 may expose a portion of the second reflective electrode RE2 by passing through the first inorganic film TCF1. The second transparent electrode TE2 may be arranged in the second contact hole CN2 and come into contact with (e.g., may contact) the second reflective electrode RE2.

The third transparent electrode TE3 may be arranged on the upper surface of the third reflective electrode RE3, and the third transparent electrode TE3 and the third reflective electrode RE3 may be in contact with each other.

When the lower electrodes LE1, LE2, and LE3 are connected to the second connection electrode CNE2, the first contact hole CN1 and the second contact hole CN2 may not overlap the first connection contact hole CNT-1 and the second connection contact hole CNT-2 due to process limitations. The first connection contact hole CNT-1 and the second connection contact hole CNT-2 may be formed to be spaced and/or apart (e.g., spaced apart or separated) from the first and second contact holes CN1 and CN2, e.g., in the first and/or second directions DR1 and/or DR2. In such cases, the pixel-defining film PDL to be described in more detail later may cover the first connection contact hole CNT-1 and the second connection contact hole CNT-2 and the first and second contact holes CN1 and CN2 to prevent or reduce the likelihood of them being viewed from the outside. For example, in order to adjust for the first and/or second connection contact holes CNT-1 and/or CNT-2 being at a distance horizontally from the contact hole connecting them to the lower electrodes LE1, LE2, and LE3 of the light-emitting element, a larger contact hole may have to be made for the lower electrodes LE1, LE2, and LE3 so that they can still electrically connect to the signal transmission region SCL via the first and/or second connection contact holes CNT-1 and/or CNT-2. As this larger contact hole would be covered by the pixel-defining layer PDL so that it is not visible to the outside, the area not included in the light-emitting areas (e.g., the pixel regions PXA) would increase, resulting in an increased spacing between the light-emitting areas. Accordingly, the areas of the lower electrodes LE1, LE2, and LE3 covered by the pixel-defining film PDL may be increased, and the aperture ratios of the first to third pixel regions PXA-1, PXA-2, and PXA-3 (see, e.g., FIG. 9) may be reduced, limiting the overall resolution of the display area DA.

However, according to one or more embodiments of the present disclosure, the plugs MTP in contact with the second connection electrode CNE2 may protrude from the upper surface of the fifth insulating layer INS5 and come in contact with the lower electrodes LE1, LE2, and LE3. The transparent electrodes TE1, TE2, and TE3 may be in contact with the reflective electrodes RE1, RE2, and RE3 through the first contact hole CN1 and the second contact hole CN2 overlapping the plugs MTP. Accordingly, as the number of the contact holes covered by the pixel-defining film PDL decreases, the areas of the lower electrodes LE1, LE2, and LE3 exposed from the pixel-defining film PDL may increase. Accordingly, as the aperture ratios of the first to third pixel regions PXA-1, PXA-2, and PXA-3 (see, e.g., FIG. 9) increase, and an electronic device 10_2b (see, e.g., FIG. 3) having a high resolution may be implemented.

The display element layer DP-ED of the display panel DP may include the pixel-defining film PDL. The pixel-defining film PDL may be arranged on at least a portion of the lower electrodes LE1, LE2, and LE3. The pixel-defining film PDL may cover a portion of the upper surface and the side surfaces of the transparent electrodes TE1, TE2, and TE3, the side surfaces of the differential film TCF, and the side surfaces of the reflective electrodes RE1, RE2, and RE3. The pixel-defining film PDL may cover the first contact hole CN1 and the second contact hole CN2.

The pixel-defining film PDL may include a pixel opening that exposes at least a portion of the upper surface of the transparent electrode TE1, TE2, or TE3 included in the lower electrode LE1, LE2, or LE3, and the pixel opening may define the first to third light-emitting regions PXA-1, PXA-2, and PXA-3.

The pixel-defining film PDL may include an inorganic material. The pixel-defining film PDL may include at least one of silicon oxide (SiOₓ), silicon nitride (SiNₓ), or silicon oxynitride (SiOₓN_{y}). The pixel-defining film PDL may include, for example, silicon oxide (SiOₓ). The pixel-defining film PDL according to one or more embodiments of the present disclosure may include an organic material.

A side surface of the pixel-defining film PDL defining the pixel opening may have a set or predetermined taper angle. The side surface of the pixel-defining film PDL may have a taper angle of about 40 degrees or more. The side surface of the pixel-defining film PDL may have a taper angle of, for example, about 75 degrees to about 90 degrees. Because the pixel-defining film PDL includes an inorganic material, the side surface of the pixel-defining film PDL may have a high taper angle of about 75 degrees or more.

In the first to third light-emitting elements ED-1, ED-2, and ED-3, the organic layer OL may be provided as a common layer (e.g., as a layer that is a continuous layer across, e.g., across the entirety of, the display region DA). The organic layer OL may include at least one light-emitting layer. The first to third light-emitting elements ED-1, ED-2, and ED-3 may each have a tandem structure.

The organic layer OL may overlap the first to third light-emitting regions PXA-1, PXA-2, and PXA-3 and the non-light-emitting region NPXA. In this specification, the overlapping of one component with another is not limited to having the same area and shape as each other on a plane (e.g., in a plan view) and includes cases in which they have different areas and/or shapes. The organic layer OL may include at least a plurality of light-emitting layers EML-1, EML-2, and EML-3 (see, e.g., FIG. 12).

Referring to FIG. 12, the organic layer OL according to one or more embodiments of the present disclosure may include a hole transport region HTR, a first light-emitting layer EML-1, a light-emitting auxiliary portion EA, a second light-emitting layer EML-2, a third light-emitting layer EML-3, and an electron transport region ETR. In the light-emitting element ED, the hole transport region HTR, the first light-emitting layer EML-1, the light-emitting auxiliary portion EA, the second light-emitting layer EML-2, the third light-emitting layer EML-3, and the electron transport region ETR may be provided as common layers.

The light-emitting element ED may be to emit white light and may include the first light-emitting layer EML-1, the second light-emitting layer EML-2, and the third light-emitting layer EML-3 that generate light of different wavelength ranges. In one or more embodiments of the present disclosure, the thickness of each of the hole transport region HTR, the light-emitting auxiliary portion EA, and the electron transport region ETR included in the light-emitting element ED may be provided such that red light, green light, or blue light undergoes an n-th order resonance. In one or more embodiments, the thickness of the aforementioned differential film TCF (see, e.g., FIG. 10) may also be provided such that red light, green light, or blue light emitted from each of the light-emitting layers EML-1, EML-2, and EML-3 of the light-emitting element ED undergoes an n-th order resonance.

As the first to third light-emitting layers EML-1, EML-2, and EML-3 provided as common layers may be deposited without a mask, pixels with a smaller area may be formed. Because a large amount of pixels with smaller areas may be arranged on a plane (e.g., in a plan view), the display panel DP according to one or more embodiments of the present disclosure may implement high resolution. In the light-emitting element ED, the hole transport region HTR may be provided on the lower electrode LE and the differential film TCF. The lower electrode LE may correspond to the lower electrodes LE1, LE2, and LE3 described above.

The hole transport region HTR may have a single layer made of a single material, a single layer made of a plurality of different materials, or a multi-layer structure having a plurality of layers made of a plurality of different materials.

The hole transport region HTR may include a hole injection layer HIL, a first hole transport layer HTL, and a first sub-hole control layer AIL-1 that are sequentially stacked. In one or more embodiments, at least one of the hole injection layer HIL, the first hole transport layer HTL, or the first sub-hole control layer AIL-1 may not be provided.

The first sub-hole control layer AIL-1 may be arranged adjacent to the first light-emitting layer EML-1 that generates the first light. The first sub-hole control layer AIL-1 may be formed to have a highest occupied molecular orbital (HOMO) energy level and a lowest unoccupied molecular orbital (LUMO) energy level that facilitate the movement of holes. Accordingly, the light-emitting element ED including the first sub-hole control layer AIL-1 may prevent or reduce an increase in driving voltage. In one or more embodiments, the first sub-hole control layer AIL-1 may block or reduce the number of electrons that may move from the first light-emitting layer EML-1 to the hole transport region HTR. Therefore, the display panel DP including the light-emitting element ED that includes the first sub-hole control layer AIL-1 may have an improved display lifespan.

The electron transport region ETR may be provided on the light-emitting auxiliary portion EA. The electron transport region ETR may have a single layer made of a single material, a single layer made of a plurality of different materials, or a multi-layer structure having a plurality of layers made of a plurality of different materials. For example, the electron transport region ETR may include an anthracene-based compound.

The electron transport region ETR may include a second buffer layer BUF-2, a first electron transport layer ETL, and an electron injection layer EIL that are sequentially stacked. In one or more embodiments, at least one of the second buffer layer BUF-2, the first electron transport layer ETL, or the electron injection layer EIL may not be provided. The second buffer layer BUF-2, the first electron transport layer ETL, and the electron injection layer EIL may include the compounds of the electron transport region ETR described above. The second buffer layer BUF-2 may block or reduce the number of holes that may move from the third emitting layer EML-3 to the electron transport region ETR.

The light-emitting auxiliary portion EA arranged between the first light-emitting layer EML-1 and the third light-emitting layer EML-3 may include a first buffer layer BUF-1, a second electron transport layer ETL-A, a first charge generation layer nCGL, a second charge generation layer pCGL, a second hole transport layer HTL-A, and a second sub-hole control layer AIL-2 that are sequentially stacked. The first charge generation layer nCGL may be an n-type (kind) charge generation layer, and the second charge generation layer pCGL may be a p-type (kind) charge generation layer. In one or more embodiments, at least one of the first buffer layer BUF-1, the second electron transport layer ETL-A, the first charge generation layer nCGL, the second charge generation layer pCGL, the second hole transport layer HTL-A, or the second sub-hole control layer AIL-2 may not be provided.

The second sub-hole control layer AIL-2 may include a material different from that of the first sub-hole control layer AIL-1 described above. The second sub-hole control layer AIL-2 may include a material that assists in the generation of the second light of the second light-emitting layer EML-2, or a material that assists in the generation of the third light of the third light-emitting layer EML-3. The first sub-hole control layer AIL-1 may include a material that assists in the generation of the first light of the first light-emitting layer EML-1. However, the present disclosure is not limited thereto, and the first sub-hole control layer AIL-1 and the second sub-hole control layer AIL-2 may include the same material as each other.

The second sub-hole control layer AIL-2 may be arranged adjacent to the third light-emitting layer EML-3 configured to generate the third light or the second light-emitting layer EML-2 configured to generate the second light. The second sub-hole control layer AIL-2 may be formed to have a highest occupied molecular orbital (HOMO) energy level and a lowest unoccupied molecular orbital (LUMO) energy level that facilitate the movement of holes. Accordingly, the light-emitting element ED including the second sub-hole control layer AIL-2 may prevent or reduce an increase in driving voltage. In one or more embodiments, the second sub-hole control layer AIL-2 may block or reduce the number of electrons that may move from the second light-emitting layer EML-2 or the third light-emitting layer EML-3 to the second hole transport layer HTL-A. Therefore, the display panel DP including the light-emitting element ED that includes the second sub-hole control layer AIL-2 may have an improved display lifespan.

Referring to FIGS. 11 and 12, in the first to third light-emitting elements ED-1, ED-2, and ED-3, the upper electrode UE may be provided as a common electrode. The upper electrode UE may be a common layer having an integrated shape and overlapping the first to third light-emitting regions PXA-1, PXA-2, and PXA-3 and the non-light-emitting region NPXA. In one or more embodiments, the upper electrode UE arranged on the organic layer OL may refer to a “cathode.”

The upper electrode UE may include at least one selected from the group consisting of Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, and an oxide thereof. The upper electrode UE may be a transmissive electrode, a semi-transmissive electrode, or a reflective electrode. When the upper electrode UE is a transmissive electrode, the upper electrode UE may be made of a transparent metal oxide such as indium tin oxide (ITO), indium zinc oxide (IZO), zinc oxide (ZnO), and indium tin zinc oxide (ITZO).

When the upper electrode UE is a semi-transmissive electrode or a reflective electrode, the upper electrode UE may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgAg). In one or more embodiments, the upper electrode UE may have a multi-layer structure including a reflective or semi-transmissive film formed of the above materials and a transparent conductive film formed of indium tin oxide (ITO), indium zinc oxide (IZO), zinc oxide (ZnO), indium tin zinc oxide (ITZO), and/or the like. For example, the upper electrode UE may include an aforementioned metal material, a combination of two or more metal materials selected from among the aforementioned metal materials, oxides of the aforementioned metal materials, and/or the like.

Referring to FIG. 11, the capping layer CPL may be arranged on the upper electrode UE. The capping layer CPL may include a plurality of layers or a single layer. The capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNₓ, SiO_{y}, and/or the like.

A thin film encapsulation layer TFE may be arranged on the display element layer DP-ED. The thin film encapsulation layer TFE may protect the display element layer DP-ED from moisture, oxygen, and/or foreign substances such as dust particles. The thin film encapsulation layer TFE may include at least one inorganic film (hereinafter, an inorganic encapsulation film). In one or more embodiments, the thin film encapsulation layer TFE may include at least one organic film (hereinafter, an organic encapsulation film) and at least one inorganic encapsulation film.

The inorganic encapsulation film may protect the display element layer DP-ED from moisture/oxygen, and the organic encapsulation film may protect the display element layer DP-ED from foreign substances such as dust particles. The inorganic encapsulation film may include silicon nitride, silicon oxynitride, silicon oxide, titanium oxide, and/or aluminum oxide, but is not particularly limited thereto. The organic encapsulation film may include an acrylic-based compound, an epoxy-based compound, and/or the like. The organic encapsulation film may include a photopolymerizable organic material, but is not particularly limited thereto.

A color filter layer CFL may be arranged on the thin film encapsulation layer TFE. The color filter layer CFL may include a first color filter CF1 corresponding to the first light-emitting region PXA-1, a second color filter CF2 corresponding to the second light-emitting region PXA-2, and a third color filter CF3 corresponding to the third light-emitting region PXA-3. In one or more embodiments, the color filter layer CFL may further include a light-shielding portion. The light-shielding portion may be a black matrix. The light-shielding portion may be formed by including an organic light-shielding material or an inorganic light-shielding material which includes a black pigment and/or a black dye. The light-shielding portion may prevent or reduce light leakage and demarcate boundaries between adjacent color filters CF1, CF2, and CF3.

Each of the first to third color filters CF1, CF2, and CF3 may include a polymer photosensitive resin and a colorant. In one or more embodiments, the colorant may include a pigment and a dye. For example, a red colorant may include a red pigment and a red dye, a green colorant may include a green pigment and a green dye, and a blue colorant may include a blue pigment and a blue dye.

In FIG. 11, the first color filter CF1 may include a red pigment or a red dye, the second color filter CF2 may include a green pigment or a green dye, and the third color filter CF3 may include a blue pigment or a blue dye. For example, the first color filter CF1 arranged on the first light-emitting element ED-1 may include a red colorant, the second color filter CF2 arranged on the second light-emitting element ED-2 may include a green colorant, and the third color filter CF3 arranged on the third light-emitting element ED-3 may include a blue colorant.

In one or more embodiments of the present disclosure, the color filter layer CFL may not be provided.

An overcoat layer OC may be arranged on the color filter layer CFL. The overcoat layer OC may cover a step difference formed by components arranged below the overcoat layer OC. The overcoat layer OC may be a rigid substrate or a flexible substrate capable of being bent, folded, rolled, and/or the like.

The overcoat layer OC may be a glass substrate, a metal substrate, a polymer substrate, and/or the like. However, the present disclosure is not limited thereto, and the overcoat layer OC may be an inorganic layer, an organic layer, or a composite material layer.

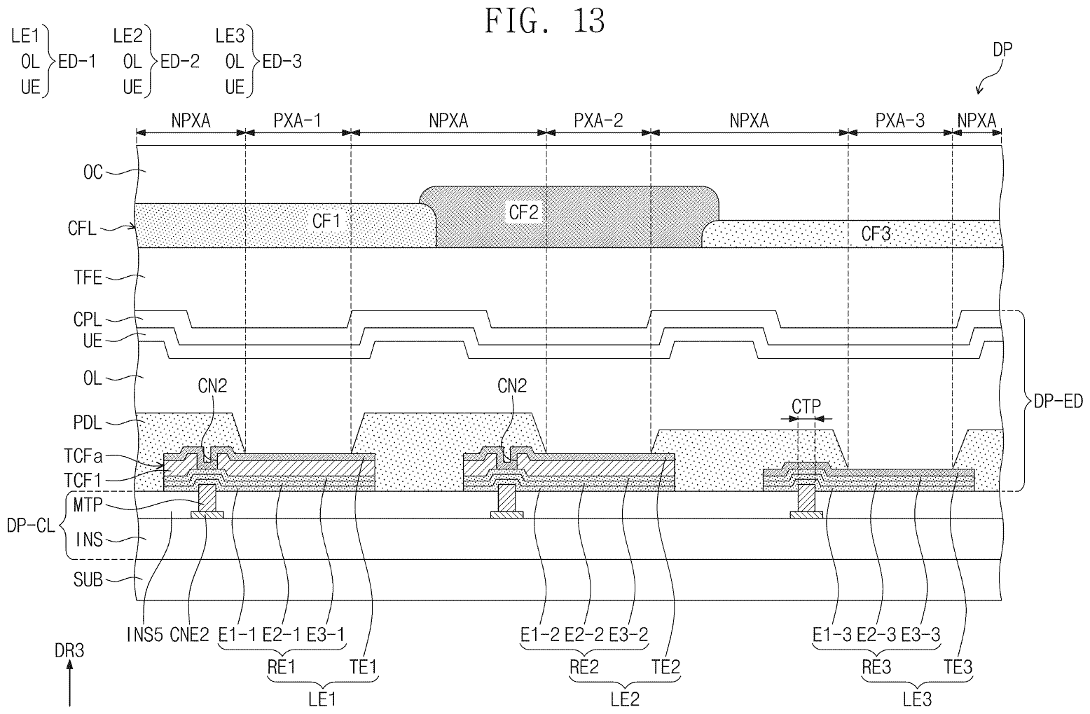

FIG. 13 is a cross-sectional view of a portion of the display region DA of the display panel DP, according to one or more embodiments of the present disclosure.

For example, FIG. 13 is a cross-sectional view of the display panel DP taken along the line I-I′ of FIG. 9, according to one or more embodiments of the present disclosure.

Among the components illustrated in FIG. 13, the descriptions of components similar or identical to those described with reference to the aforementioned drawings may not be provided or may be briefly provided.

Referring to FIG. 13, a differential film TCFa may include a first inorganic film TCF1. Unlike the differential film TCF illustrated in FIG. 11, the differential film TCFa may not include (e.g., may exclude) a second inorganic film TCF2.

The second inorganic film TCF2 may not be arranged between the first reflective electrode RE1 and the first transparent electrode TE1. Only the first inorganic film TCF1 may be arranged between the first reflective electrode RE1 and the first transparent electrode TE1. A first contact hole CN1 may be defined by the first inorganic film TCF1.

Because the second inorganic film TCF2 (see, e.g., FIG. 11) is not arranged between the first reflective electrode RE1 and the first transparent electrode TE1, the distance between the first reflective electrode RE1 and the first transparent electrode TE1 and the distance between the second reflective electrode RE2 and the second transparent electrode TE2 may be the same as each other.

When the distance between the first reflective electrode RE1 and the first transparent electrode TE1 and the distance between the second reflective electrode RE2 and the second transparent electrode TE2 may each independently be the same as each other, the color filter layer CFL may be arranged on the thin film encapsulation layer TFE. For example, the color filter layer CFL may be provided (e.g., may not be omitted).

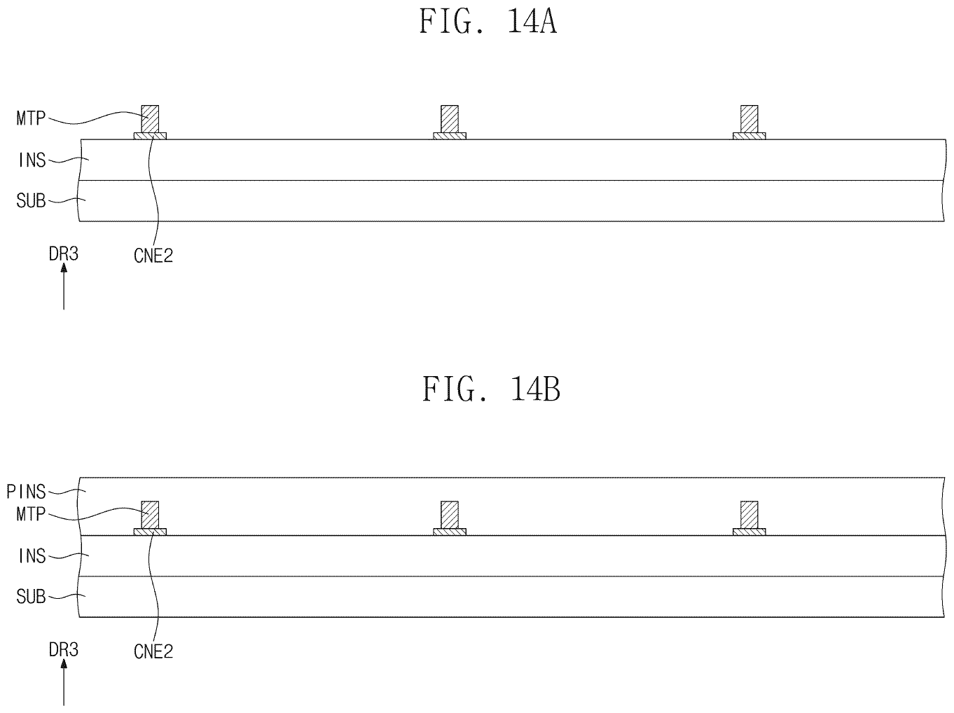

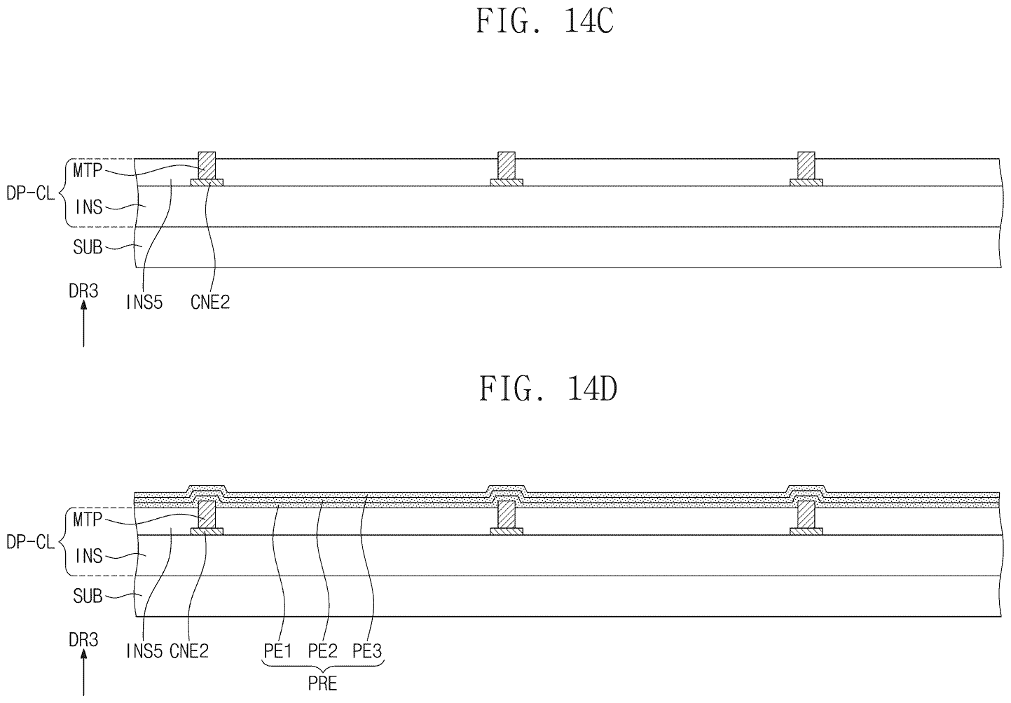

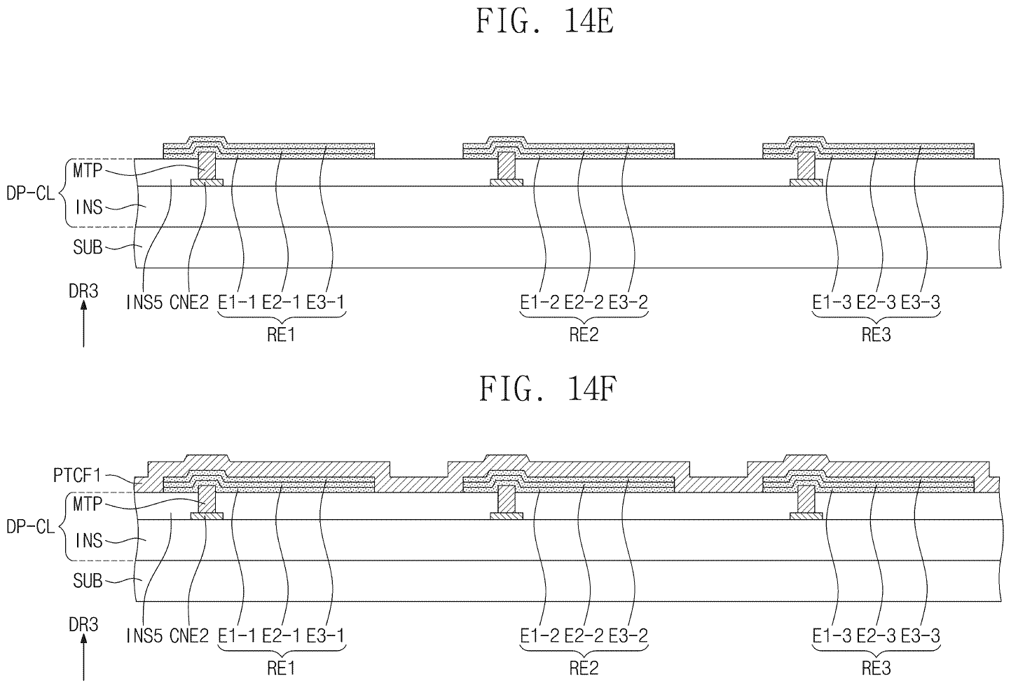

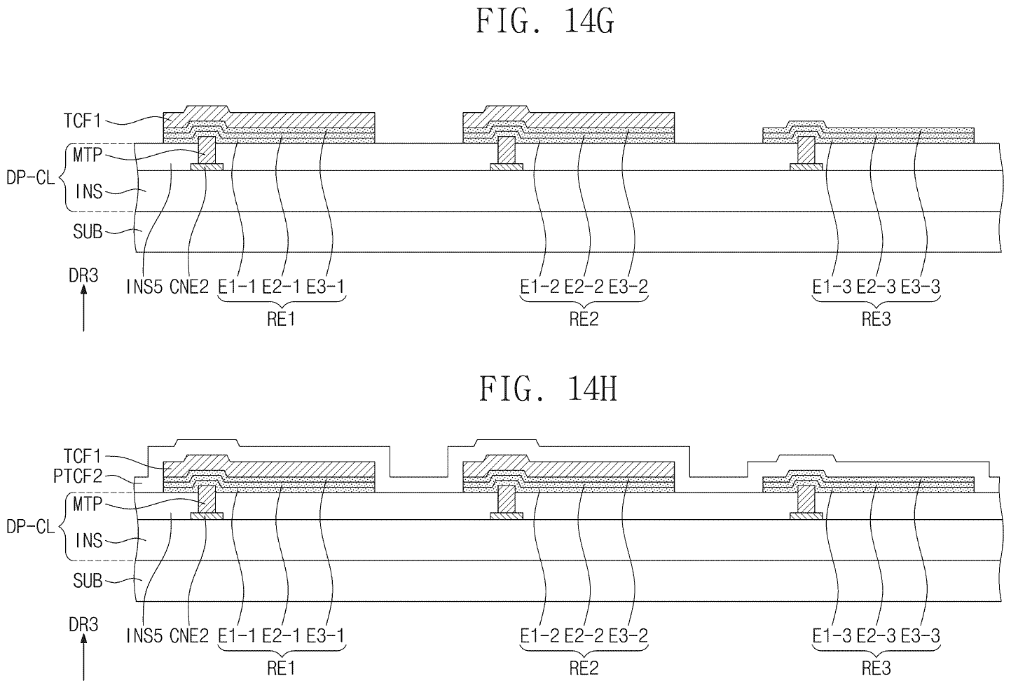

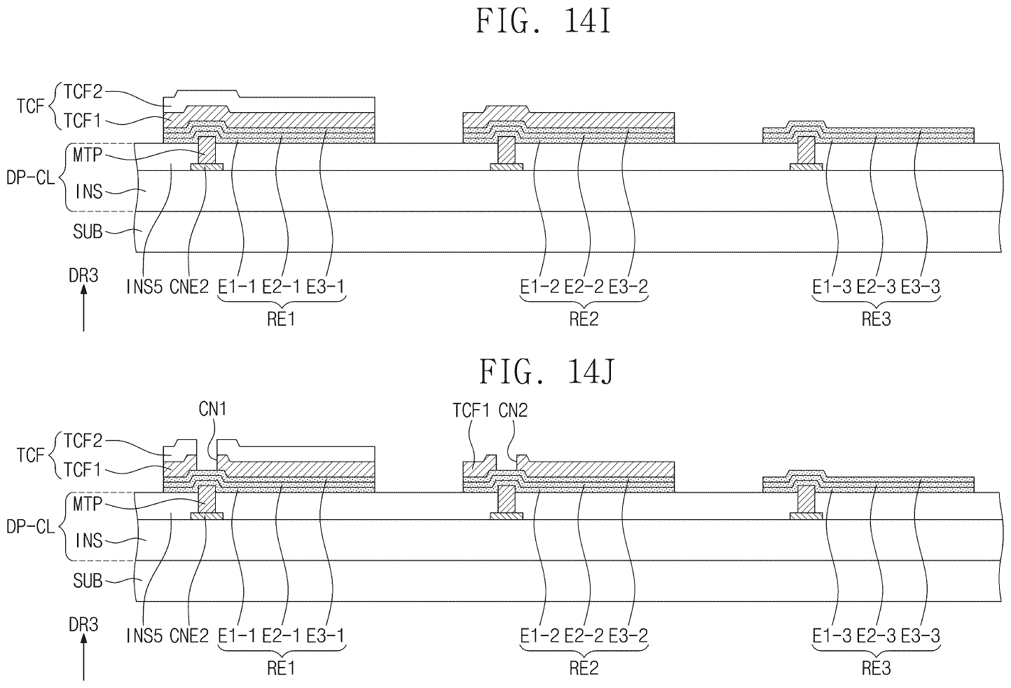

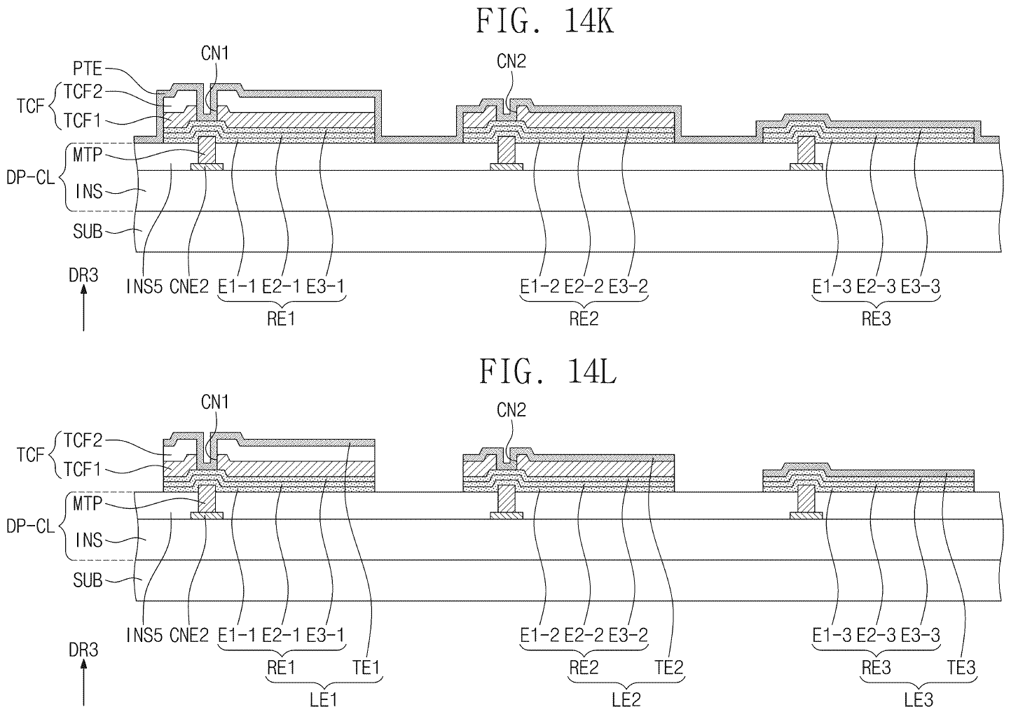

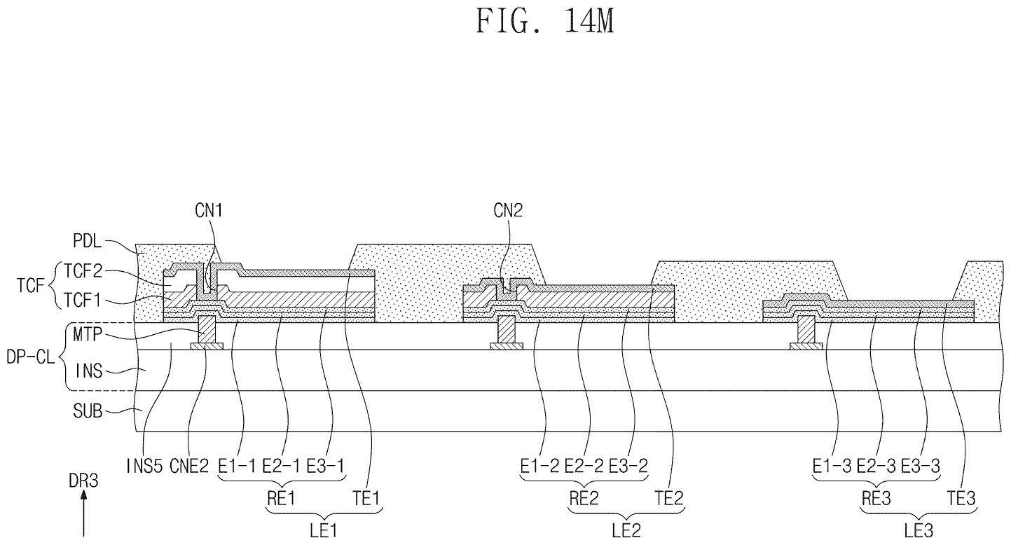

FIGS. 14A to 14M are cross-sectional views for explaining the manufacturing of the lower electrodes illustrated in FIG. 11, according to one or more embodiments of the present disclosure.

For conciseness, each of the base layer SUB and the insulating layer INS are briefly illustrated as one layer.

Among the components illustrated in FIGS. 14A to 14M, the descriptions of components similar or identical to those described with reference to the aforementioned drawings may not be provided or may be briefly provided.

Referring to FIG. 14A, a method for manufacturing the lower electrodes LE1, LE2, and LE3 may include preparing an insulating layer INS, a second connection electrode CNE2 arranged on the insulating layer INS, and plugs MTP arranged on the second connection electrode CNE2.

Referring to FIG. 14B, an organic material PINS may be applied onto the insulating layer INS, the second connection electrode CNE2, and the plugs MTP. The organic material PINS may cover the second connection electrode CNE2 and the plugs MTP.

Referring to FIG. 14B and FIG. 14C, the organic material PINS may be cured and then etched. For example, the organic material PINS may be etched using plasma generated from an etching gas containing a compound which includes carbon, hydrogen, and nitrogen as a main component. The etched organic material PINS may be defined as the fifth insulating layer INS5.

The plugs MTP may be exposed to the outside from the fifth insulating layer INS5. The plugs MTP may protrude from the upper surface of the fifth insulating layer INS5. The upper surfaces of the plugs MTP may be higher than the upper surface of the fifth insulating layer INS5.

When etching the height of the upper surfaces of the plugs MTP and the height of the upper surface of the fifth insulating layer INS5 in order to make them the same height as each other, it may not be easy to control the amount of etching of the fifth insulating layer INS5.

Because the plugs MTP protrude from the upper surface of the fifth insulating layer INS5, adjusting the amount of etching may not be desired or required to make the height of the upper surface of the fifth insulating layer INS5 equal to those of the upper surfaces of the plugs MTP. Accordingly, the process of forming the fifth insulating layer INS5 may be simplified.

Referring to FIG. 14D, the fifth insulating layer INS5 may be formed and then a preliminary reflective electrode PRE may be applied onto the fifth insulating layer INS5. The preliminary reflective electrode PRE may cover the plugs MTP in addition to the fifth insulating layer INS5.

The preliminary reflective electrode PRE may include a reflective conductive material. The preliminary reflective electrode PRE may include a preliminary first layer PE1, a preliminary second layer PE2, and a preliminary third layer PE3 that are sequentially stacked in the third direction DR3. The preliminary first layer PE1 may correspond to the first layers E1-1, E1-2, and E1-3 illustrated in FIG. 11. The preliminary second layer PE2 may correspond to the second layers E2-1, E2-2, and E2-3 illustrated in FIG. 11. The preliminary third layer PE3 may correspond to the third layers E3-1, E3-2, and E3-3 illustrated in FIG. 11.

Referring to FIGS. 14D and 14E, after depositing the preliminary reflective electrode PRE, patterns may be formed using a photoresist layer in regions respectively corresponding to the first to third light-emitting regions PXA-1, PXA-2, and PXA-3 (see, e.g., FIG. 11). Thereafter, the first to third reflective electrodes RE1, RE2, and RE3 may be formed, for example, using wet etching.

Referring to FIG. 14F, after forming the first to third reflective electrodes RE1, RE2, and RE3, a first inorganic material PTCF1 may be applied onto the first to third reflective electrodes RE1, RE2, and RE3. The first inorganic material PTCF1 may cover the first to third reflective electrodes RE1, RE2, and RE3 and the fifth insulating layer INS5. The first inorganic material PTCF1 may be formed using a chemical vapor deposition (CVD) method. The first inorganic material PTCF1 may include the same material as the first inorganic film TCF1 of, for example, FIG. 11.

Referring to FIGS. 14F and 14G, a photoresist layer may be applied onto the first inorganic material PTCF1 in regions corresponding to the first light-emitting region PXA-1 (see, e.g., FIG. 11) and the second light-emitting region PXA-2 (see, e.g., FIG. 11). Thereafter, the first inorganic films TCF1 may be formed using dry etching.

Referring to FIG. 14H, a second inorganic material PTCF2 may be applied onto the first to third reflective electrodes RE1, RE2, and RE3. The second inorganic material PTCF2 may cover the upper surface of the first inorganic film TCF1, the upper surface of the fifth insulating layer INS5, and the upper surface of the third reflective electrode RE3.

Referring to FIGS. 14H and 141, a photoresist layer may be applied onto the second inorganic material PTCF2 in a region corresponding to the first light-emitting region PXA-1 (see, e.g., FIG. 11). Thereafter, a second inorganic film TCF2 may be formed using dry etching.

Referring to FIG. 14J, the differential film TCF may be etched to form a first contact hole CN1 and a second contact hole CN2. For example, after applying a photoresist layer onto the differential film TCF, the first contact hole CN1 and the second contact hole CN2 may be formed using dry etching.

For example, in FIG. 14J, the first contact hole CN1 and the second contact hole CN2 are illustrated as being formed concurrently (e.g., simultaneously) through a same etching process, but without being limited thereto, in one or more embodiments, after the first contact hole CN1 is formed, the second contact hole CN2 may be formed through a different etching process.

The first contact hole CN1 may overlap the first reflective electrode RE1. The first contact hole CN1 may be defined by the first and second inorganic films TCF1 and TCF2. The first contact hole CN1 may overlap the plug MTP.

The second contact hole CN2 may overlap the second reflective electrode RE2. The second contact hole CN2 may be defined by the first inorganic film TCF1. The second contact hole CN2 may overlap the plug MTP.

Referring to FIG. 14K, after forming the first and second contact holes CN1 and CN2, a preliminary transparent electrode PTE may be applied. The preliminary transparent electrode PTE may include a conductive material having transparency. The preliminary transparent electrode PTE may cover the differential film TCF, the fifth insulating layer INS5, and the third reflective electrode LE3.

Referring to FIG. 14K and FIG. 14L, after depositing the preliminary transparent electrode PTE, patterns may be formed using a photoresist layer in regions respectively corresponding to the first to third light-emitting regions PXA-1, PXA-2, and PXA-3 (see, e.g., FIG. 11). Hereafter, the first to third transparent electrodes TE1, TE2, and TE3 may be formed using wet etching.

The first transparent electrode TE1 may be in contact with the first reflective electrode RE1 through the first contact hole CN1. The second transparent electrode TE2 may be in contact with the second reflective electrode RE2 through the second contact hole CN2. The third transparent electrode TE3 may be arranged on and in contact with the upper surface of the third reflective electrode RE3.

Referring to FIG. 14M, a pixel-defining film PDL may be formed between the lower electrodes LE1, LE2, and LE3 and over edges of the lower electrodes LE1, LE2, and LE3. Portions of the lower electrodes LE1, LE2, and LE3 may be exposed by the pixel-defining film PDL.

Referring to FIG. 11, after forming of pixel-defining film PDL, an organic layer OL, an upper electrode UE, a capping layer CPL, and a thin film encapsulation layer TFE may be sequentially formed on the pixel-defining film PDL and the lower electrodes LE1, LE2, and LE3.

According to one or more embodiments of the present disclosure, reflective electrodes may be electrically connected to transistors through plugs, and transparent electrodes may be connected to the reflective electrodes through contact holes overlapping the plugs. Accordingly, as the contact holes electrically connecting the reflective electrodes and the transistors to each other may not be provided, the number of the contact holes may be reduced. Accordingly, the area of the anode electrode exposed to the outside by the pixel-defining film may be increased, thus allowing for an increase in the light-emitting regions. Therefore, because the aperture ratio of a light-emitting region may increase, the electronic device may implement high resolution, as more pixels can be provided in the same area.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer comprising first to third light-emitting regions and a non-light-emitting region;
a circuit element layer on the base layer and comprising an inorganic insulating layer covering a plurality of transistors and an organic insulating layer on the inorganic insulating layer;
a plurality of plugs in through-holes defined in the organic insulating layer, the plugs electrically connected to the transistors;
lower electrodes electrically connected to the plugs and comprising first to third reflective electrodes respectively overlapping the first to third light-emitting regions and first to third transparent electrodes respectively on and electrically connected to the first to third reflective electrodes;
an organic layer on the lower electrode and comprising a light-emitting layer; and
an upper electrode on the organic layer,
wherein the plugs protrude toward the lower electrodes beyond an upper surface of the organic insulating layer.

2. The display device of claim 1, wherein the circuit element layer further comprises:
a first connection electrode in a first connection contact hole defined in the inorganic insulating layer and connected to a transistor of the plurality of transistors; and
a second connection electrode in a second connection contact hole defined in the inorganic insulating layer and connected to the first connection electrode,
wherein the plugs are on and connected to the second connection electrode.

3. The display device of claim 1, wherein the first to third reflective electrodes cover portions of the plugs protruding from the organic insulating layer.

4. The display device of claim 3, wherein portions of the first to third reflective electrodes overlapping the plugs protrude further than remaining portions of the reflective electrodes not overlapping the plugs.

5. The display device of claim 3, further comprising a plurality of differential films between the first reflective electrode and the first transparent electrode and between the second reflective electrode and the second transparent electrode,
wherein:
a first contact hole is defined by a differential film of the plurality of differential films located on the first reflective electrode;
a second contact hole is defined by a differential film of the plurality of differential films located on the second reflective electrode;
the first transparent electrode is in the first contact hole and connected to the first reflective electrode; and
the second transparent electrode is in the second contact hole and connected to the second reflective electrode.

6. The display device of claim 5, wherein the first contact hole and the second contact hole each overlap at least one of the plugs.

7. The display device of claim 6, further comprising a pixel-defining film on the circuit element layer, the pixel-defining film defining pixel openings that expose at least a portion of each of the lower electrodes,
wherein the pixel-defining film covers the first contact hole and the second contact hole.

8. The display device of claim 5, wherein the plurality of differential films comprise a first inorganic film and a second inorganic film, each of which contains an inorganic material.

9. The display device of claim 8, wherein:
the first inorganic film and the second inorganic film are between the first reflective electrode and the first transparent electrode; and
the first inorganic film is between the second reflective electrode and the second transparent electrode.

10. The display device of claim 9, wherein a first distance between the first reflective electrode and the first transparent electrode is greater than a second distance between the second reflective electrode and the second transparent electrode.

11. The display device of claim 9, wherein the first contact hole is deeper than the second contact hole.

12. The display device of claim 5, wherein a first distance between the first reflective electrode and the first transparent electrode is the same as a second distance between the second reflective electrode and the second transparent electrode.

13. The display device of claim 12, further comprising a color filter layer comprising first to third color filters on the upper electrode and respectively overlapping the first to third light-emitting regions.

14. The display device of claim 1, wherein the plugs comprise a metal.

15. A method for manufacturing a display device, the method comprising:
supplying a base layer comprising first to third light-emitting regions and a non-light-emitting region,
forming an inorganic insulating layer on the base layer and covering a plurality of transistors, and
forming a plurality of plugs on the inorganic insulating layer and electrically connected to the transistors;
applying an organic material onto the inorganic insulating layer and the plugs, hardening the organic material, and then etching a portion of the organic material to form an organic insulating layer;
applying a preliminary reflective electrode onto the organic insulating layer and then etching the preliminary reflective electrode to form first to third reflective electrodes respectively overlapping the first to third light-emitting regions;
applying an inorganic material onto the first to third reflective electrodes and then etching the inorganic material to form a differential film on the first reflective electrode and the second reflective electrode;
etching the differential film to form a first contact hole overlapping the first reflective electrode and a second contact hole overlapping the second reflective electrode;
applying a preliminary transparent electrode onto the differential film and then etching the preliminary transparent electrode to form first to third transparent electrodes on the first to third reflective electrodes, respectively;
forming an organic layer on the first to third transparent electrodes; and
forming an upper electrode on the organic layer,
wherein the plugs protrude upward from an upper surface of the organic insulating layer.

16. The method of claim 15, wherein the first to third reflective electrodes cover the plugs.

17. The method of claim 16, wherein:
the first transparent electrode is in the first contact hole and connected to the first reflective electrode; and
the second transparent electrode is in the second contact hole and connected to the second reflective electrode.

18. The method of claim 16, wherein the first contact hole and the second contact hole overlap the plugs.

19. The method of claim 16, wherein the forming of the differential film comprises:
applying a first inorganic material onto the first to third reflective electrodes and then etching the first inorganic material to form a first inorganic film on the first reflective electrode and the second reflective electrode; and
applying a second inorganic material onto the first to third reflective electrodes and then etching the second inorganic material to form a second inorganic film on the first inorganic film.

20. The method of claim 19, wherein the plugs comprise a metal.

21. An electronic device comprising:
a case comprising a first case and a second case on one side of the first case;
a display device between the first case and the second case; and
an optical system inside the first case,
wherein the display device comprises:
a base layer comprising first to third light-emitting regions and a non-light-emitting region;
a circuit element layer on the base layer and comprising an inorganic insulating layer covering a plurality of transistors and an organic insulating layer on the inorganic insulating layer;
a plurality of plugs in through-holes defined in the organic insulating layer, the plugs electrically connected to the transistors;
lower electrodes electrically connected to the plugs and comprising first to third reflective electrodes respectively overlapping the first to third light-emitting regions and first to third transparent electrodes respectively on and electrically connected to the first to third reflective electrodes;
an organic layer on the lower electrode and comprising a light-emitting layer; and
an upper electrode on the organic layer,
wherein the plugs protrude toward the lower electrodes beyond an upper surface of the organic insulating layer.
